(19) United States
(12) Patent Application Publication
(10) Pub. No.: US 2026/0247696 A1
(43) Pub. Date: Aug. 20, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Yi-Ju CHEN, Tainan City (TW); Chun-Ting LEE, Hsinchu County (TW); Che-Chia CHANG, Taipei City (TW); Yi-Ren CHEN, Taoyuan City (TW); Chun-Sheng LIANG, Puyan Township (TW); Shih-Hsun CHANG, Hsinchu (TW)

(21) Appl. No.: 19/053,639

(22) Filed: Feb. 14, 2025

(51) Int. Cl. H10D 84/83; H10D 30/00; H10D 30/01; H10D 30/43; H10D 62/10; H10D 62/13; H10D 64/01; H10D 64/23; H10D 84/01

(52) U.S. Cl. CPC H10D 84/832; H10D 30/014; H10D 30/0191; H10D 30/43; H10D 30/502; H10D 62/121; H10D 62/151; H10D 64/017; H10D 64/256; H10D 84/013; H10D 84/0135; H10D 84/0149; H10D 84/8312

(57) ABSTRACT

A method of forming a semiconductor structure, including forming a fin structure, forming a dummy gate over the fin structure, forming side spacers on opposite sides of the fin structure, forming source/drain features on the opposite sides of the dummy gate, and replacing the dummy gate with a metal gate. The fin structure includes first and second semiconductor layers alternately stacked. The method further includes forming trenches exposing the source/drain features, etching the source/drain features to extend the trenches to form contact trenches, and forming source/drain contacts in the contact trenches. The bottoms of the trenches are higher than the bottom of the topmost second semiconductor layer, and the bottoms of the contact trenches are lower than the top of the second bottommost second semiconductor layer. One source/drain contact includes a silicide layer formed on the source/drain feature and a metal portion formed on the silicide layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down generally provides benefits by increasing production efficiency and lowering associated costs. Such scaling down has also increased the complexity of processing and manufacturing ICs and, for these advancements to be realized, similar developments in IC processing and manufacturing are developed.

As IC technologies progress towards smaller technology nodes, multi-gate metal-oxide-semiconductor field effect transistors (multi-gate MOSFETs, or multi-gate devices) have been introduced to improve gate control by increasing gate-channel coupling, reducing off-state current, and reducing short-channel effects. A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, and 4 are perspective views of a workpiece at various fabrication stages, in accordance with some embodiments of the present disclosure.

FIGS. 5A, 6A, 7A, 8A, 9A, 10A, 11A, 12A, 13A, and 14A are X-Z cross-sectional views of the workpiece at various fabrication stages along a line A-A′ of FIG. 4, in accordance with some embodiments of the present disclosure.

FIGS. 5B, 6B, 7B, 8B, 9B, 10B, 11B, 12B, 13B, and 14B are X-Z cross-sectional views of the workpiece at various fabrication stages along a line B-B′ of FIG. 4, in accordance with some embodiments of the present disclosure.

FIGS. 5C, 6C, 7C, 8C, 9C, 10C, 11C, 12C, 13C, and 14C are Y-Z cross-sectional views of the workpiece at various fabrication stages along a line C-C′ of FIG. 4, in accordance with some embodiments of the present disclosure.

FIGS. 5D, 6D, 7D, 8D, 9D, 10D, 11D, 12D, 13D, and 14D are Y-Z cross-sectional views of the workpiece at various fabrication stages along a line D-D′ of FIG. 4, in accordance with some embodiments of the present disclosure.

FIGS. 15A and 15B are X-Z cross-sectional views of a semiconductor structure along lines A-A′ and B-B′ of FIG. 4, respectively, in accordance with some alternative embodiments of the present disclosure.

FIGS. 15C and 15D are Y-Z cross-sectional views of the semiconductor structure along lines C-C′ and D-D′ of FIG. 4, respectively, in accordance with some alternative embodiments of the present disclosure.

FIGS. 16A, 17A, 19A, 20A, and 21A are X-Z cross-sectional views of a workpiece at various fabrication stages along line A-A′ of FIG. 4, in accordance with some alternative embodiments of the present disclosure.

FIGS. 16B, 17B, 19B, 20B, and 21B are X-Z cross-sectional views of the workpiece at various fabrication stages along line B-B′ of FIG. 4, in accordance with some alternative embodiments of the present disclosure.

FIGS. 16C, 17C, 18, 19C, 20C, and 21C are Y-Z cross-sectional views of the workpiece at various fabrication stages along line C-C′ of FIG. 4, in accordance with some alternative embodiments of the present disclosure.

FIGS. 16D, 17D, 19D, 20D, and 21D are Y-Z cross-sectional views of the workpiece at various fabrication stages along line D-D′ of FIG. 4, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The GAA transistor structures described below may be patterned by any suitable method. For example, the structures may be patterned by using one or more photolithography processes, including double-patterning processes or multi-patterning processes. In general, double-patterning processes or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structures.

In advanced technology node, the critical poly pitch (CPP) (the pitch between a gate and an adjacent gate) and the critical dimensions (CDs) of source/drain (S/D) features and S/D contacts of the GAA transistors are scaled down as the dimension of the GAA transistors continue to scale down. Since the CDs of the S/D features and the S/D contacts are scaled down, the contact resistance between the S/D contacts and the S/D features is increased, and thus the performance of the GAA transistors is limited by the increased contact resistance. Therefore, a novel structure and fabricating method are needed to reduce the contact resistance between the S/D contacts and the S/D features, so as to improve the performance of the GAA transistors.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods that include extending the S/D trench for forming the deep S/D contact, so that the deep S/D contact formed in the extended S/D trench extends into or is embedded in the S/D feature. The deep S/D contact has larger volume itself and can provide more contact area between the S/D contact and the S/D feature, so that the bulk resistivity of the S/D contact and the contact resistance between the S/D contact and the S/D feature can be reduced. Moreover, since the deep contact is closer to the lower nanostructure, it can promote the access to the lower channel, so as to mitigate the current crowding effect. Furthermore, the extended S/D trench may be formed to have a lower portion with awl-shape, such that the portion of silicide layer of the S/D contact formed in the lower portion is merged into a bulk silicide. Compared with the silicide in a form of layer, the silicide in a form of bulk can reduce the resistance between the metal portion and the silicide portion inside the S/D contact, so as to reduce contact resistance between the S/D contact and the S/D feature further.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

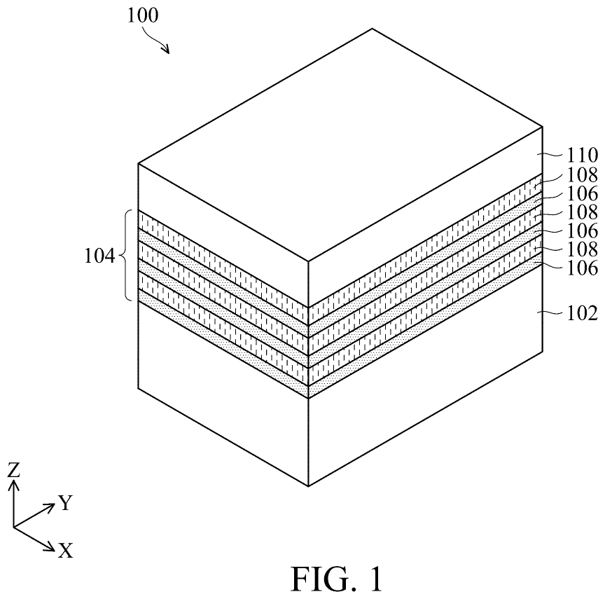

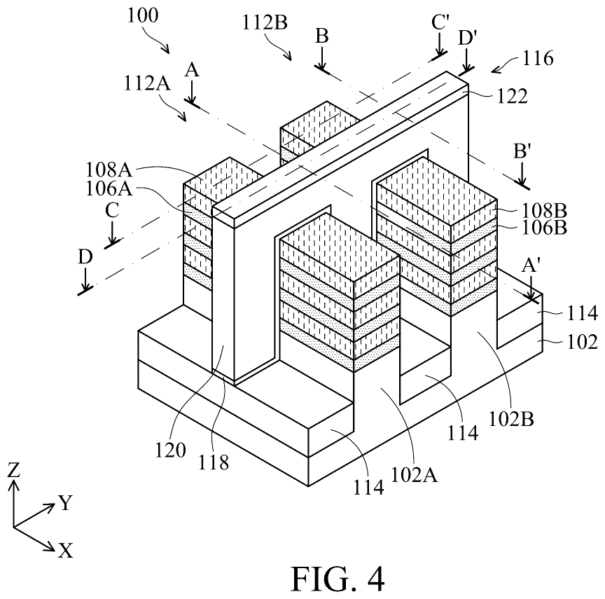

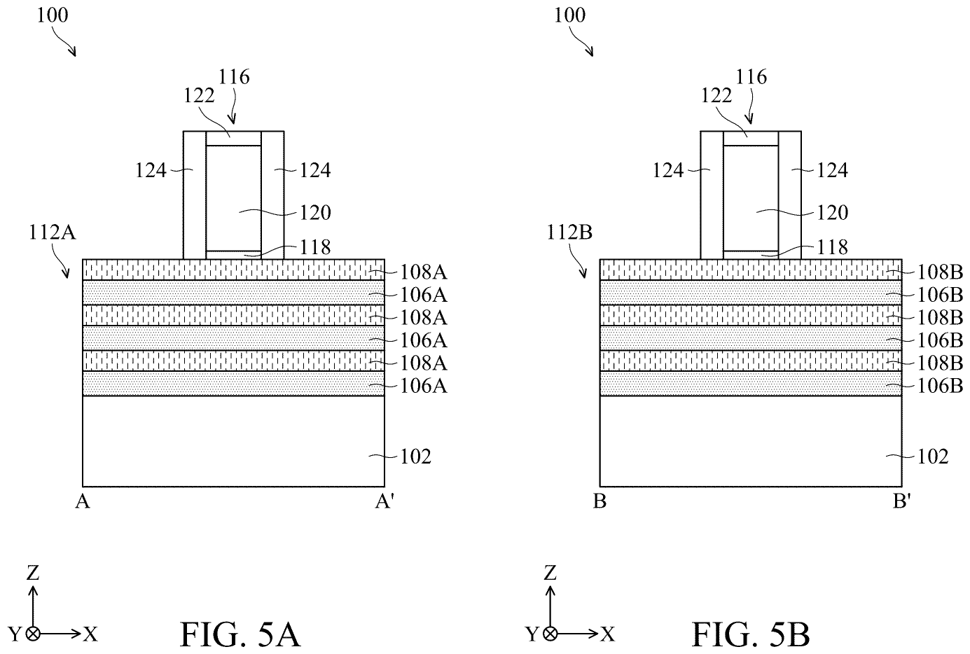

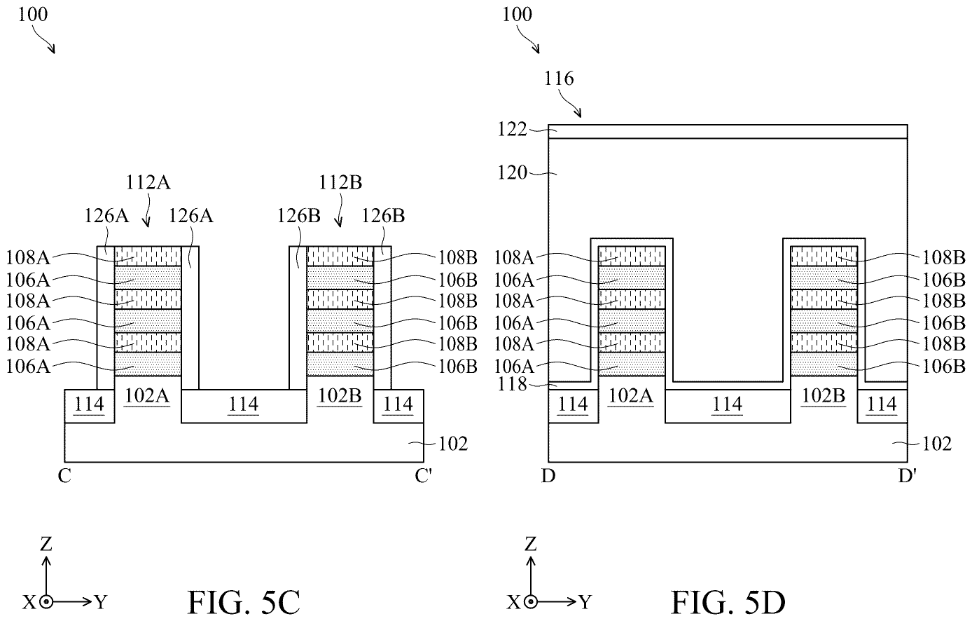

FIGS. 1, 2, 3, and 4 are perspective views of a workpiece 100 at various fabrication stages, in accordance with some embodiments. FIGS. 5A, 6A, 7A, 8A, 9A, 10A, 11A, 12A, 13A, and 14A are X-Z cross-sectional views of the workpiece 100 at various fabrication stages along line A-A′ of FIG. 4, in accordance with some embodiments. FIGS. 5B, 6B, 7B, 8B, 9B, 10B, 11B, 12B, 13B, and 14B are X-Z cross-sectional views of the workpiece 100 at various fabrication stages along line B-B′ of FIG. 4, in accordance with some embodiments. FIGS. 5C, 6C, 7C, 8C, 9C, 10C, 11C, 12C, 13C, and 14C are Y-Z cross-sectional views of the workpiece 100 at various fabrication stages along line C-C′ of FIG. 4, in accordance with some embodiments. FIGS. 5D, 6D, 7D, 8D, 9D, 10D, 11D, 12D, 13D, and 14D are Y-Z cross-sectional views of the workpiece 100 at various fabrication stages along line D-D′ of FIG. 4, in accordance with some embodiments.

Referring to FIG. 1, the workpiece 100 includes a substrate 102 and a stack 104 over the substrate 102, in accordance with some embodiments. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

In some embodiments, the stack 104 includes semiconductor layers 106 and semiconductor layers 108 that are stacked in an alternating manner in the Z-direction. The semiconductor layers 106 and the semiconductor layers 108 may have different semiconductor compositions. In some embodiments, the semiconductor layers 106 are formed of silicon germanium, and the semiconductor layers 108 are formed of silicon. In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and the semiconductor layers 108 are formed alternatingly, one-after-another, to form the stack 104. It should be noted that, three layers of the semiconductor layers 106 and three layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer structure or a multi-layer structure. In some embodiments, the hard mask layer 110 is a single layer structure and includes a silicon germanium layer. In some embodiments, the hard mask layer 110 is a multi-layer structure and includes a silicon nitride layer and a silicon oxide layer over the silicon nitride layer.

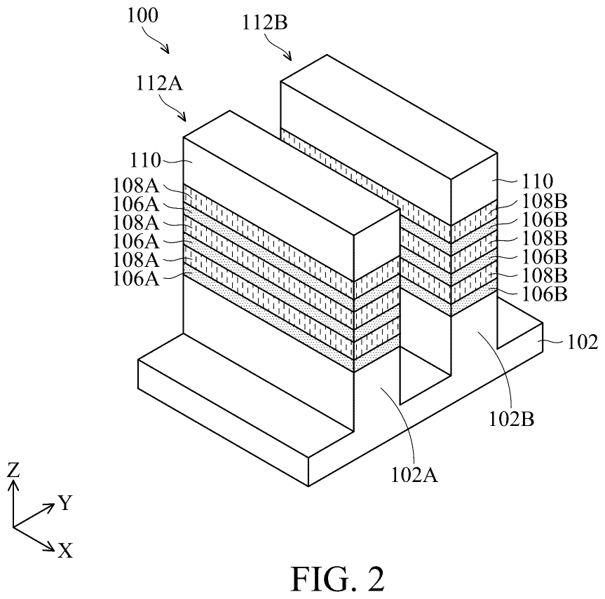

Referring to FIG. 2, the substrate 102, the stack 104, and the hard mask layer 110 are then patterned to form a fin structure 112A and a fin structure 112B (may be collectively referred to as fin structures 112) over the substrate 102, in accordance with some embodiments. In some embodiments, the fin structures 112A includes a base fin 102A (which may also be referred to as protrusion 102A) formed from a portion of the substrate 102 and a stack portion formed from the stack 104 over the base fin 102A, and the fin structures 112B includes a base fin 102B (which may also be referred to as protrusion 102B) formed from a portion of the substrate 102 and a stack portion formed from the stack 104 over the base fin 102B, as shown in FIG. 2. The stack portion of the fin structure 112A may include semiconductor layers 106A and semiconductor layers 108A that are alternately stacked over the substrate 102, and the stack portion of the fin structure 112B may include semiconductor layers 106B and semiconductor layers 108B that are alternately stacked over the substrate 102. The semiconductor layers 106A and 106B are formed from the semiconductor layers 106, and the semiconductor layers 108A and 108B are formed from the semiconductor layers 108.

In some embodiments, the base fins 102A and 102B protrude from the substrate 102. Each of the fin structures 112 may extend lengthwise in the X-direction and extend vertically in the Z-direction over the substrate 102, and arranged in the Y-direction. In some embodiments, widths of the fin structures 112 along the Y-direction are the same. Although the two fin structures 112A and 112B are formed and shown herein, more fin structures may be formed, such as three or more fin structures.

The fin structures 112 may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 112 by etching the stack 104 and the substrate 102. The etching process may include dry etching, wet etching, reactive ion etching (RIE), and/or other suitable processes. In some embodiments, the photolithography processes include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam (e-beam) writing, and ion-beam writing.

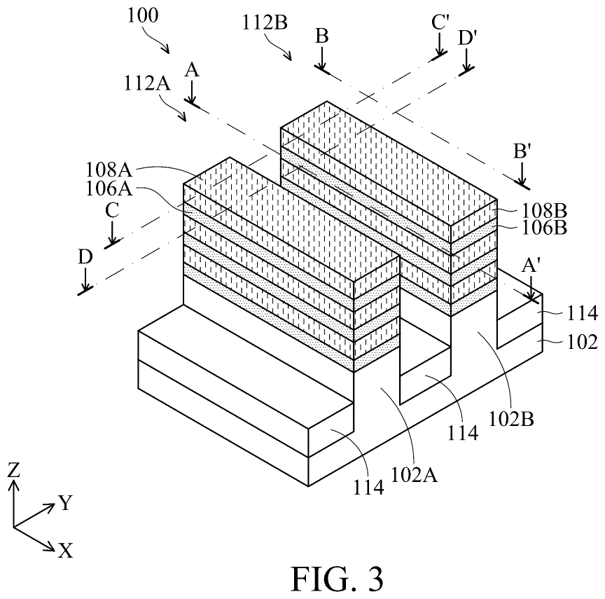

Referring to FIG. 3, isolation structures 114 are formed, in accordance with some embodiments. In some embodiments, after the fin structures 112 are formed, the hard mask layer 110 over the fin structures 112 is removed and the isolation structures 114 are formed over the substrate 102. In some embodiments, the isolation structures 114 are formed between the fin structures 112. In other embodiments, the isolation structures 114 are formed around the fin structures 112. More specifically, the isolation structures 114 are formed between and around the base fins (e.g., base fins 102A and 102B) of the fin structures 112. The isolation structures 114 may also be referred to as shallow trench isolation (STI) feature.

In some embodiments, a dielectric material for the isolation structures 114 is first deposited over the workpiece 100. Specifically, the dielectric material is deposited and formed over the fin structures 112 and the substrate 102 to cover the fin structures 112 and the substrate 102. In some embodiments, the dielectric material is formed to wrap around the fin structures 112. In some embodiments, the dielectric material may include silicon oxide (SiO₂), silicon nitride (SiN), silicon oxynitride (SiON), fluorine-doped silicate glass (FSG), a low-k dielectric material, combinations thereof, and/or other suitable materials. Exemplary low-k dielectric materials include carbon doped silicon oxide, xerogel, aerogel, amorphous fluorinated carbon, parylene, BCB-based dielectric material, polyimide, other low-k dielectric materials, or combinations thereof.

In some embodiments, the dielectric material is deposited using a deposition process, such as CVD, subatmospheric CVD (SACVD), flowable CVD (FCVD), ALD, spin-on coating, and/or other suitable process. The deposited dielectric material is then thinned and planarized, for example by a chemical mechanical polishing (CMP) process, until the hard mask layer 110 is removed. The planarized dielectric material is further recessed by a dry etching process, a wet etching process, and/or a combination thereof to form the isolation structures 114. In some embodiments, the stack portions of the fin structures 112 rise above the isolation structures 114 while the base fins 102A and 102B are surrounded by the isolation structures 114, as shown in FIG. 3. In other words, the top surfaces of the substrate 102 (specifically, the top surfaces of the base fins 102A and 102B) are higher than the top surfaces of the isolation structures 114. In some embodiments, before the formation of the isolation structures 114, a liner layer may be conformally deposited over the substrate 102 using a deposition process, such as CVD, ALD, high-density plasma CVD (HDPCVD), MOCVD, RPCVD, PECVD, LPCVD, atomic layer CVD (ALCVD), atmospheric pressure CVD (APCVD), FCVD, or combinations thereof.

Referring to FIG. 4, a dummy gate structure 116 may be formed over the fin structures 112 and the isolation structures 114, in accordance with some embodiments. The dummy gate structure 116 may be configured to extend lengthwise in the Y-direction and wrap around top surfaces and side surfaces of the fin structures 112. In some embodiments, in order to form the dummy gate structure 116, a dummy gate dielectric material for a dummy gate dielectric layer 118 is first formed over the fin structures 112 and the isolation structures 114. In some embodiments, the dummy gate dielectric layer 118 may include a dielectric material such as a nitride (e.g., SiN, SiON), a carbide (e.g., silicon carbide (SiC)), an oxide (e.g., SiO₂), or some other suitable materials.

Then, in some embodiments, a dummy gate electrode material for a dummy gate electrode layer 120 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, a hard mask layer 122 is formed over the dummy gate electrode material. In some embodiments, the hard mask layer 122 may be formed by using photolithography and removal (e.g., etching) processes. In some embodiments, the hard mask layer 122 may include photoresist materials or hard mask materials. In some embodiments, the hard mask layer 122 may include multiple layers, such as a silicon nitride layer and a silicon oxide layer. After the formation of the hard mask layer 122, a removal process (e.g., etching) may be performed to remove portions of the dummy gate electrode material for the dummy gate electrode layer 120 and the dummy gate dielectric material for the dummy gate dielectric layer 118 that are not directly underlie the hard mask layer 122, thereby forming the dummy gate structure 116. The dummy gate structure 116 may include the dummy gate dielectric layer 118, the dummy gate electrode layer 120, and the hard mask layer 122.

The dummy gate structure 116 may undergo a gate replacement process through subsequent processing to form a metal gate, such as a high-k metal gate, as discussed in greater detail below. It should be noted that, one dummy gate structure 116 is shown in FIG. 4, which are for illustrative purposes only and the workpiece 100 may include more dummy gate structures for more transistors sharing source/drain regions.

Referring to FIGS. 5A to 5D, after the formation of the dummy gate structure 116, gate spacers 124, side spacers 126A, and side spacers 126B are formed, in accordance with some embodiments. In some embodiments, the gate spacers 124 are formed on opposite sidewalls of the dummy gate structure 116 in the X-direction, and over the top surface of the topmost semiconductor layers 108A and 108B. In some embodiments, the side spacers 126A are formed on opposite sidewalls of the fin structure 112A in the Y-direction and over the isolation structures 114, and the side spacers 126B are formed on opposite sidewalls of the fin structure 112B in the Y-direction and over the isolation structures 114.

The gate spacers 124, the side spacers 126A, and the side spacers 126B may include SiN, SiO₂, SiC, silicon oxycarbide (SiOC), SiON, silicon carbon nitride (SiCN), silicon oxycarbon nitride (SiOCN), carbon doped oxide, nitrogen doped oxide, porous oxide, or combinations thereof. In some embodiments, the gate spacers 124, the side spacers 126A, and the side spacers 126B include a low-k dielectric material, such as those described herein. The gate spacers 124, the side spacers 126A, and the side spacers 126B may include a single layer or a multi-layer structure.

In some embodiments, a spacer layer (containing the dielectric material) is conformally deposited over the fin structures 112 and the dummy gate structure 116. Then, an anisotropic etching process is performed to remove horizontal portions of the spacer layer from the top surfaces of the isolation structures 114, the fin structures 112, and the dummy gate structure 116. After the anisotropic etching process, the portions of the spacer layer formed on sidewall surfaces of the dummy gate structure 116 substantially remain and become the gate spacers 124. After the anisotropic etching process, the portions of the spacer layer formed on sidewall surfaces of the fin structures 112A substantially remain and become the side spacers 126A, and the portions of the spacer layer formed on sidewall surfaces of the fin structures 112B substantially remain and become the side spacers 126B. In some embodiments, the gate spacers 124 are also in partial contact with the fin structures 112 and the isolation structures 114, and the side spacers 126A and 126B are also formed over the isolation structures 114.

In some embodiments, the anisotropic etching process is a dry (e.g., plasma) etching process. Additionally or alternatively, the deposition of the spacer layer may also involve chemical oxidation, thermal oxidation, CVD, PVD, ALD, HDPCVD, MOCVD, RPCVD, PECVD, LPCVD, ALCVD, APCVD, FCVD, and/or other suitable methods. The gate spacers 124 may also be interchangeably referred to as top spacers.

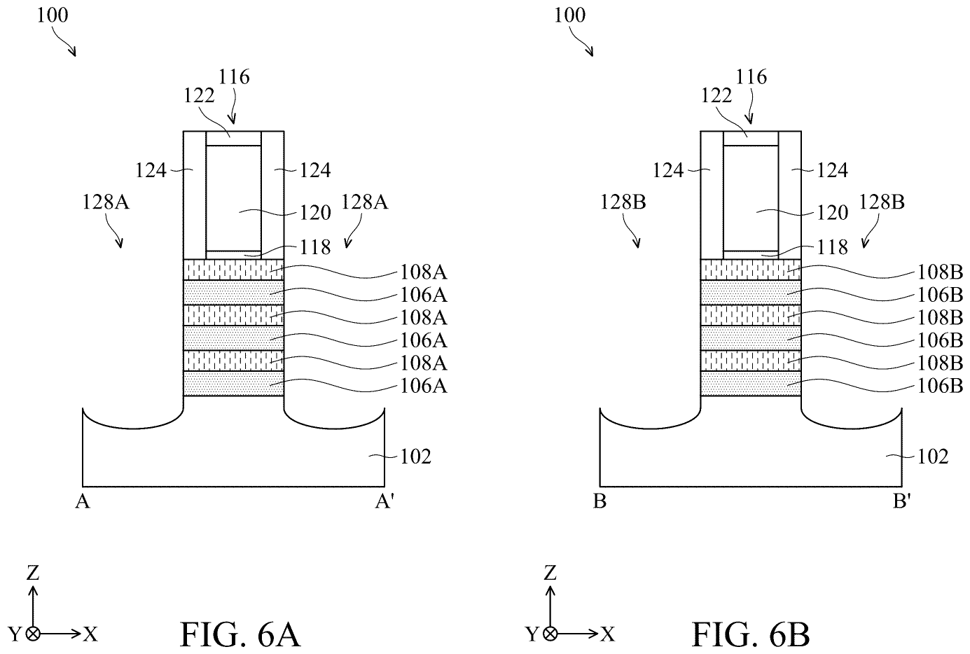

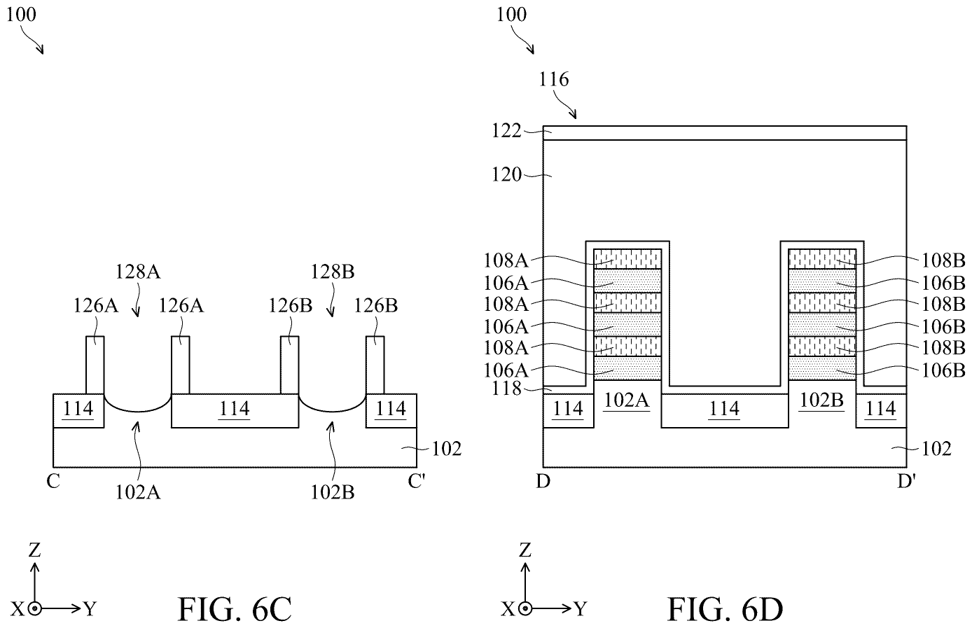

Referring to FIGS. 6A to 6D, the fin structures 112 are recessed to form source/drain trenches in the fin structures 112 (or passing through the semiconductor layers 106A, 106B and 108A, 108B) for source/drain regions, in accordance with some embodiments. In some embodiments, the source/drain trenches 128A are formed in the fin structure 112A and on opposite sides of the dummy gate structure 116 in the X-direction, and the source/drain trenches 128B are formed in the fin structure 112B and on opposite sides of the dummy gate structure 116 in the X-direction. Specifically, the source/drain trenches 128A and 128B may be formed by performing one or more etching processes to remove portions of the semiconductor layers 106A, 106B, 108A, and 108B and the substrate 102 (e.g., base fins 102A and 102B) that the dummy gate structure 116 and the gate spacers 124 do not cover or vertically overlap.

In some embodiments, a single etchant is used to remove the semiconductor layers 106A, 106B, 108A, and 108B and the substrate 102. In other embodiments, multiple etchants may be used to perform the etching process. In some embodiments, portions of the substrate 102 are etched, so that the source/drain trenches 128A and 128B (which may collectively be referred to as source/drain trenches 128) extend into the substrate, and each has a concave surface in the substrate 102, as shown in FIGS. 6A to 6D. In some embodiments, the side spacers 126A and 126B formed on opposite sidewalls of the fin structures 112A and 112B in the Y-direction are partially etched during the etching process, so that the heights of the side spacers 126A and 126B are reduced, as shown in FIG. 6C.

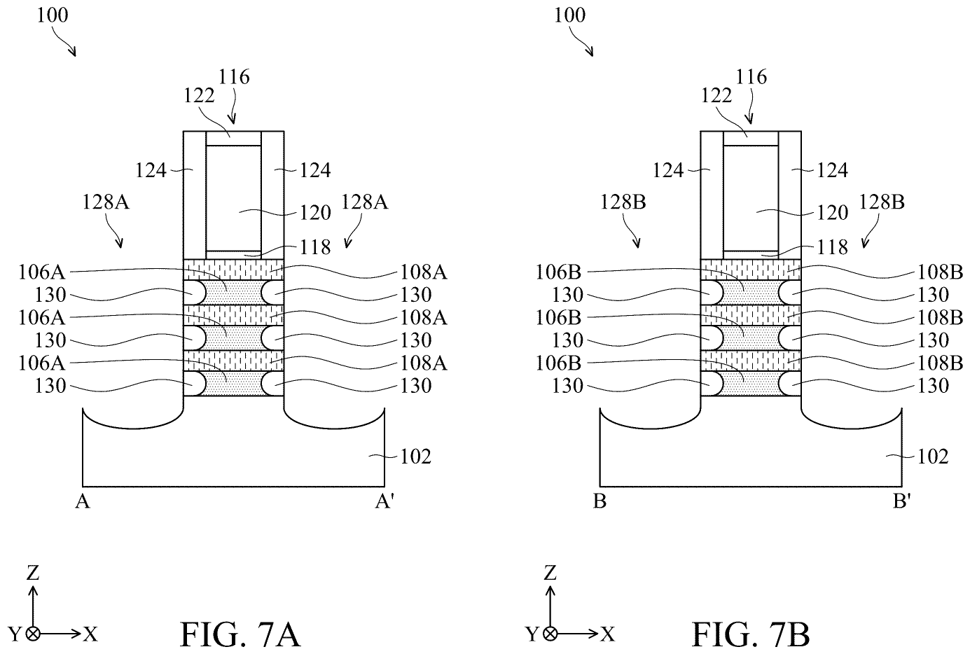

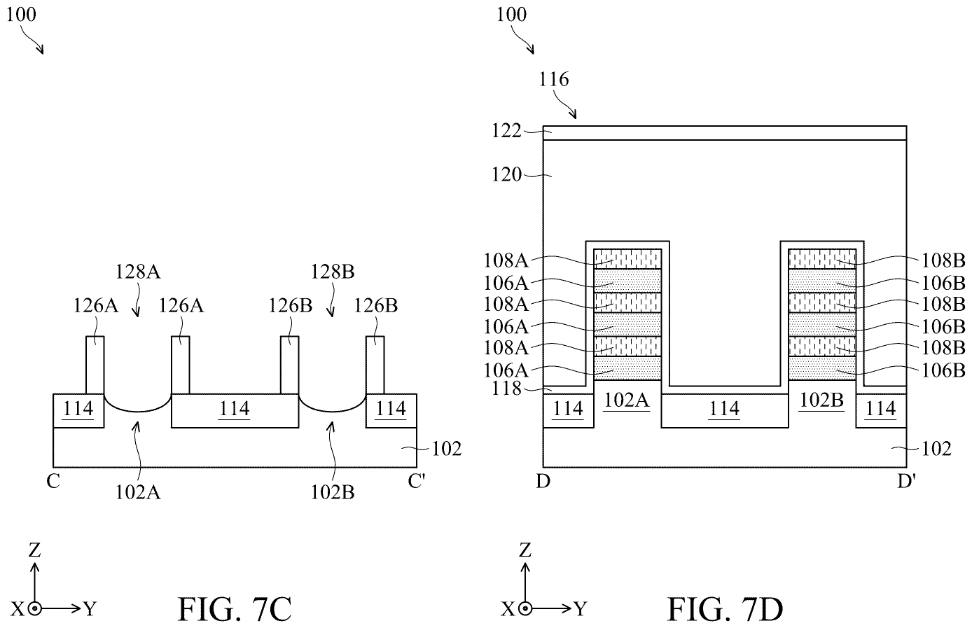

Referring to FIGS. 7A to 7D, the inner spacers 130 are formed between the semiconductor layers 108 (including the semiconductor layers 108A and 108B) as well as between the semiconductor layer 108 and the substrate 102, in accordance with some embodiments. In some embodiments, the semiconductor layers 106A exposed in the source/drain trenches 128A and the semiconductor layers 106B exposed in the source/drain trenches 128B are partially recessed through a selective etching process, and the semiconductor layers 108A and 108B are not etched. More specifically, the selective etching process is performed that selectively etches the side portions of the semiconductor layers 106A and 106B below the gate spacers 124 through the source/drain trenches 128A and 128B, with minimal etching (or substantially no etching) of the semiconductor layers 108A and 108B and the substrate 102. After the selective etching process, inner spacer recesses are vertically formed between the semiconductor layers 108 as well as between the semiconductor layers 108 and the substrate 102, below the gate spacers 124. The selective etching process may be a dry etching process, a wet etching process, other suitable etching process, or a combination thereof.

Next, in some embodiments, a spacer layer is conformally formed into the source/drain trenches 128A and 128B and the inner spacer recesses. More specifically, a deposition process is performed to form the spacer layer into the source/drain trenches 128A and 128B and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (alternatively, completely) fills the source/drain trenches 128A and 128B and fully fills the inner spacer recesses. The deposition process is configured to ensure that the spacer layer fills the inner spacer recesses. Furthermore, the spacer layer is also conformally formed on the gate spacers 124, the side spacers 126A, the side spacers 126B, and the isolation structures 114.

The spacer layer may include a material that is different than the materials of the semiconductor layers 108 and the gate spacers 124 to achieve desired etching selectivity during the etching process. In some embodiments, the spacer layer includes a dielectric material that includes silicon, oxygen, carbon, nitrogen, other suitable material, or combinations thereof (e.g., SiO₂, SiON, SiOC, SiCN, SiOCN). In some embodiments, the spacer layer includes a low-k dielectric material, such as those described herein.

Then, in some embodiments, the inner spacers 130 are formed to fill the inner spacer recesses between the semiconductor layers 108 (including the semiconductor layers 108A and 108B) as well as between the semiconductor layer 108 and the substrate 102. More specifically, an etching process is performed to selectively etch the spacer layer to form the inner spacers 130 with minimal etching (or substantially no etching) of the semiconductor layers 108, the substrate 102, the dummy gate structure 116, and the gate spacers 124 (including the side spacers 126A and 126B). The etching process may be an anisotropic etching process, removing the portions of the spacer layer that the dummy gate structure 116 and gate spacers 124 do not cover or vertically overlap. The spacer layer on the gate spacers 124 (including the side spacers 126A and 126B) and the isolation structures 114 are removed.

In some embodiments, sidewalls of the inner spacers 130 are aligned to the sidewalls of the gate spacers 124 and the semiconductor layers 108A or 108B. Therefore, the inner spacers 130 are formed on opposite sides of the dummy gate structure 116 in the X-direction. In some embodiments, in the fin structure 112A, the inner spacers 130 are also vertically between the semiconductor layers 108A as well as between the semiconductor layer 108A and the substrate 102. Similarly, in the fin structure 112B, the inner spacers 130 are also vertically between the semiconductor layers 108B as well as between the semiconductor layer 108B and the substrate 102. In other embodiments, sidewalls of the inner spacers 130 have concave surfaces exposed by the source/drain trenches 128A or 128B. In some embodiments, sidewalls of the inner spacers 130 in contact with the semiconductor layers 106A or 106B have convex surfaces.

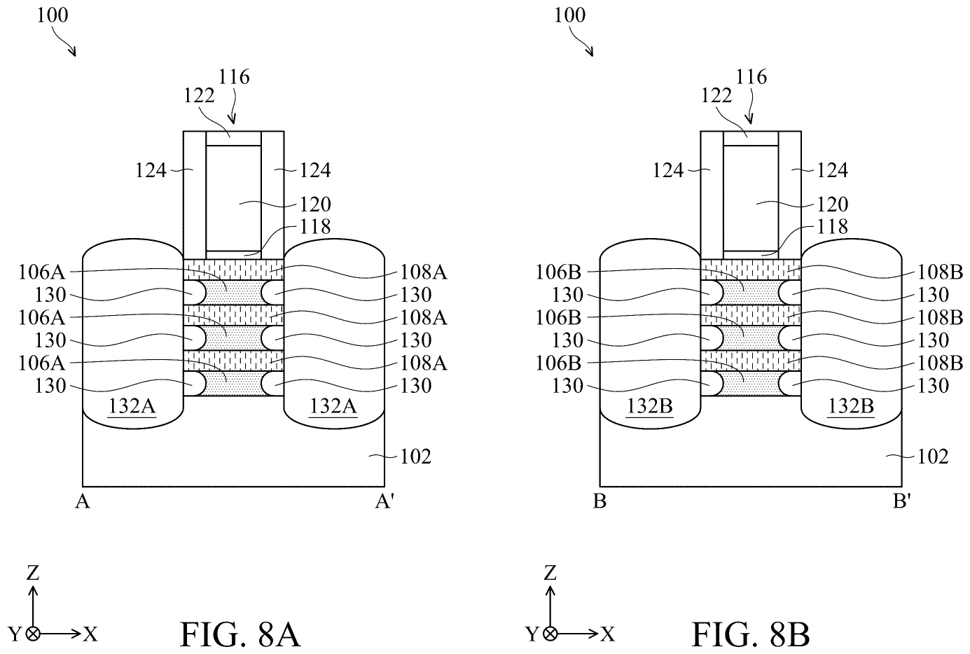

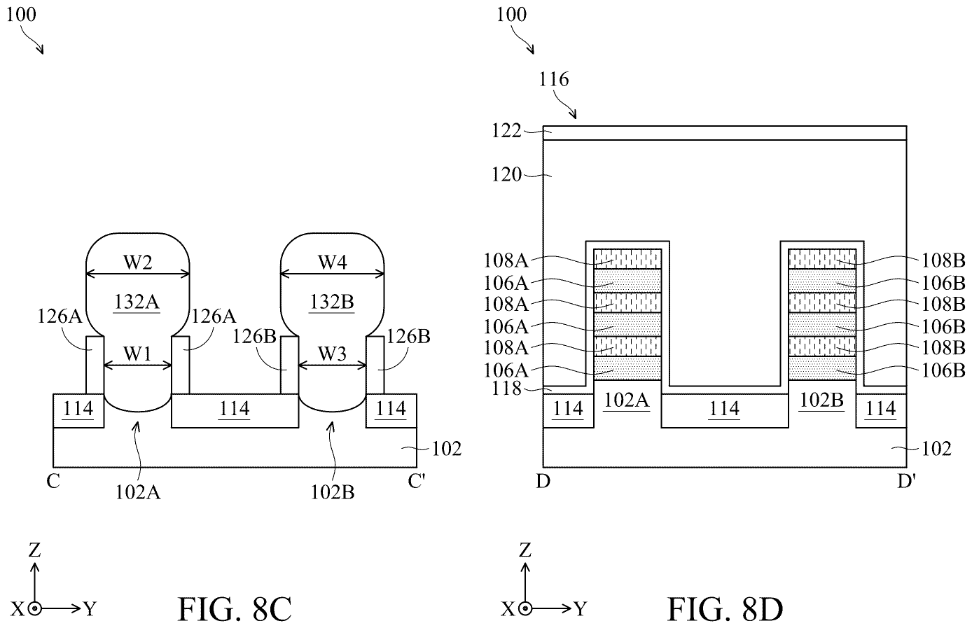

Referring to FIGS. 8A to 8D, source/drain features are formed in the source/drain trenches, in accordance with some embodiments. In some embodiments, source/drain features 132A are formed in the source/drain trenches 128A formed in the fin structure 112A, as shown in FIGS. 8A and 8C. In some embodiments, source/drain features 132B are formed in the source/drain trenches 128B formed in the fin structure 112B, as shown in FIGS. 8B and 8C. In some embodiments, the side spacers 126A are disposed on opposite sides of the source/drain features 132A in the Y-direction, and the top surfaces of the source/drain features 132A are higher than the top surfaces of the side spacers 126A in the Z-direction. In further embodiments, the side spacers 126A are disposed on lower portions of the source/drain features 132A in the Z-direction. In some embodiments, the side spacers 126B are disposed on opposite sides of the source/drain features 132B in the Y-direction, and the top surfaces of the source/drain features 132B are higher than the top surfaces of the side spacers 126B in the Z-direction. In further embodiments, the side spacers 126B are disposed on lower portions of the source/drain features 132B in the Z-direction. The source/drain features 132A and 132B may also be referred to as source/drain, or source/drain regions. In some embodiments, source/drain feature(s) may refer to a source or a drain, individually or collectively dependent upon the context.

In some embodiments, in the Y-direction, portions of the source/drain features 132A lower than the top surfaces of the side spacers 126A have a width W1, and portions of the source/drain features 132A higher than the top surfaces of the side spacers 126A have a width W2, as shown in FIG. 8C. In some embodiments, the width W2 is greater than the width W1. In some embodiments, in the Y-direction, portions of the source/drain features 132B lower than the top surfaces of the side spacers 126B have a width W3, and portions of the source/drain features 132B higher than the top surfaces of the side spacers 126B have a width W4, as shown in FIG. 8C. In some embodiments, the width W4 is greater than the width W3.

In some embodiments, the source/drain features 132A are disposed on opposite sides of the dummy gate structure 116 in the X-direction and in the fin structure 112A. In some embodiments, the source/drain features 132A are connected to and in contact with the semiconductor layers 108A. That is, the source/drain features 132A are adjacent to and attached to opposite sides of the semiconductor layers 108A in the fin structure 112A. In some embodiments, the source/drain features 132B are disposed on opposite sides of the dummy gate structure 116 in the X-direction and in the fin structure 112B. In some embodiments, the source/drain features 132B are connected to and in contact with the semiconductor layers 108B. That is, the source/drain features 132B are adjacent to and attached to opposite sides of the semiconductor layers 108B in the fin structure 112B.

In some embodiments, the source/drain features 132A may have top surfaces that extend higher than the top surface of the topmost semiconductor layer 108A (e.g., in the Z-direction). Similarly, the source/drain features 132B may have top surfaces that extend higher than the top surface of the topmost semiconductor layer 108B (e.g., in the Z-direction). In some embodiments, the semiconductor layers 108A serve as channels to connect one source/drain feature 132A to another source/drain feature 132A. Similarly, in some embodiments, the semiconductor layers 108B serve as channels to connect one source/drain feature 132B to another source/drain feature 132B. Therefore, the semiconductor layers 108A and 108B may also be referred to as channels, channel layers, or channel members.

In some embodiments, the source/drain features 132A and 132B are formed using an epitaxial growth process. The epitaxial growth process may include VPE, MOCVD, MBE, or other deposition processes, such as CVD, LPCVD, PECVD, ALD, UHVCVD, RPCVD, combinations thereof, or the like. In some embodiments, the source/drain features 132A may be p-type source/drain features configured for a p-type GAA transistor or n-type source/drain features configured for an n-type GAA transistor. In some embodiments, the source/drain features 132B may be p-type source/drain features configured for a p-type GAA transistor or n-type source/drain features configured for an n-type GAA transistor.

The p-type source/drain features may include epitaxially-grown material selected from a group consisting of boron-doped SiGe, boron-doped SiGeC, boron-doped Ge, boron-doped Si, boron and carbon-doped SiGe, or a combination thereof. In some embodiments, the p-type source/drain features may be doped with p-type dopants and have a doping concentration greater than 5×10²⁰/cm³. The n-type source/drain features may include epitaxially-grown material selected from a group consisting of SiP, SiC, SiPC, SiAs, Si, or a combination thereof. In some embodiments, the n-type source/drain features are doped with n-type dopants and have a doping concentration greater than 1×10²¹/cm³. The source/drain features 132A and 132B may be doped in-situ or ex-situ. In some embodiments, one or more annealing processes may be performed to activate the dopants in the source/drain features 132A, and 132B. The annealing processes may include rapid thermal annealing (RTA) and/or laser annealing processes.

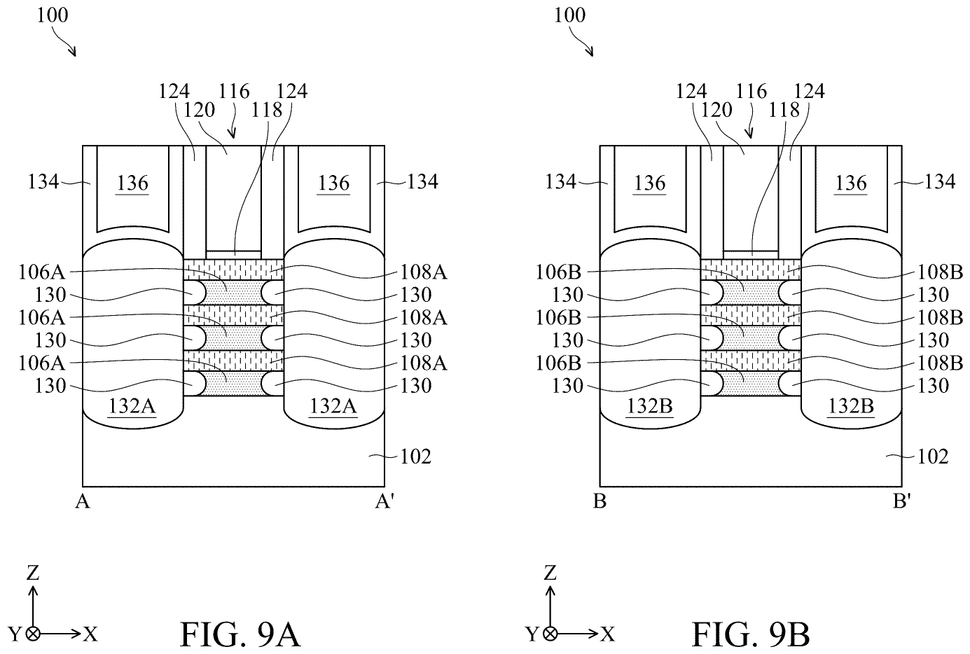

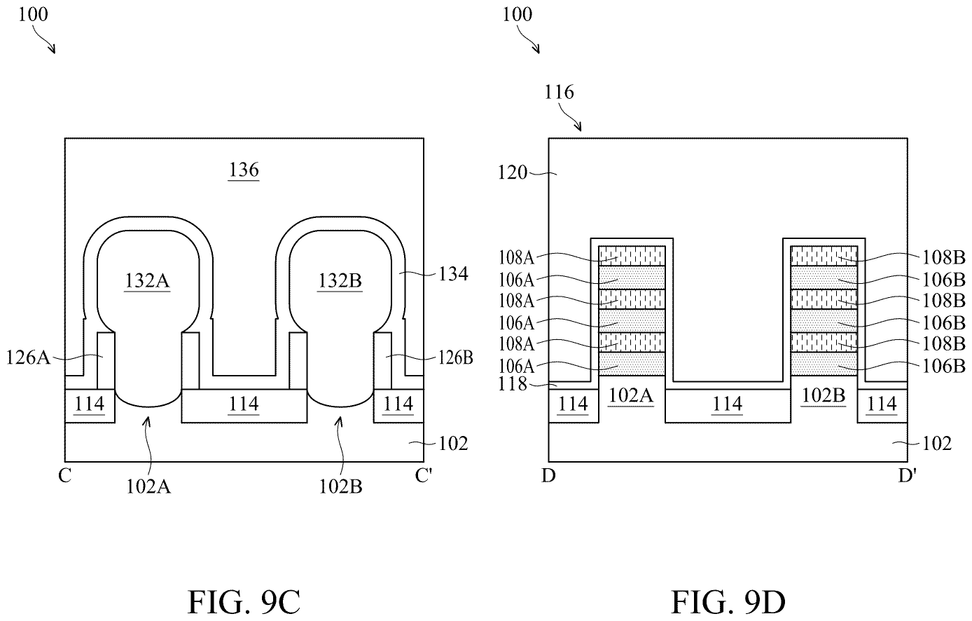

Referring to FIGS. 9A to 9D, contact etch stop layers (CESLs) 134 are formed over the source/drain features 132A and 132B, and interlayer dielectric (ILD) layers 136 are formed over the CESLs 134, in accordance with some embodiments. In some embodiments, the CESLs 134 are conformally formed on sidewalls of the gate spacers 124, on surfaces of the side spacers 126A and 126B, on surfaces of the source/drain features 132A and 132B, and over top surfaces of the isolation structures 114, as shown in FIGS. 9A to 9D. The ILD layers 136 are formed over and between the CESLs 134 to fill the spaces between the CESLs 134 or between the gate spacers 124.

The CESLs 134 may include a material that is different than ILD layers 136. The CESLs 134 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, SiN, Y₂O₃, AlON, TaCN, ZrSi, or other suitable materials. The CESLs 134 may be formed by CVD, PVD, ALD, HDPCVD, MOCVD, RPCVD, PECVD, LPCVD, ALCVD, APCVD, FCVD, or other suitable methods. The ILD layers 136 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), a low-k dielectric material, another suitable dielectric material, or a combination thereof. The ILD layers 136 may be formed by CVD, PVD, ALD, HDPCVD, MOCVD, RPCVD, PECVD, LPCVD, ALCVD, APCVD, FCVD, or other suitable methods.

Subsequent to the deposition of the CESLs 134 and the ILD layers 136, a CMP process and/or some other planarization process is performed on the CESLs 134, the ILD layers 136, the gate spacers 124, and the hard masks layers 122 until the top surfaces of the dummy gate electrode layers 120 are exposed. In some embodiments, portions of the dummy gate electrode layers 120 are removed after the planarization process.

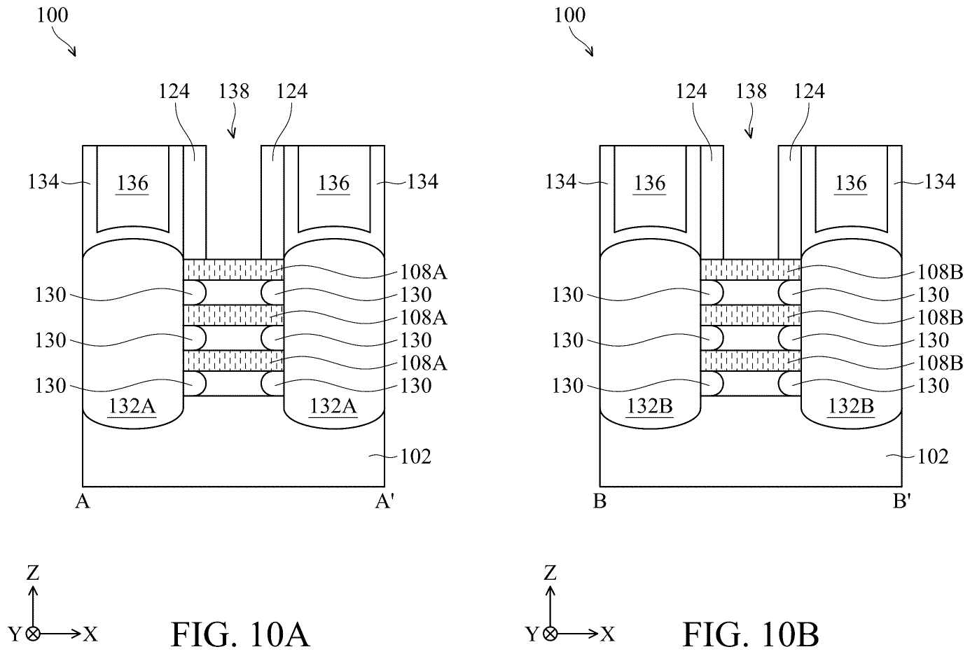

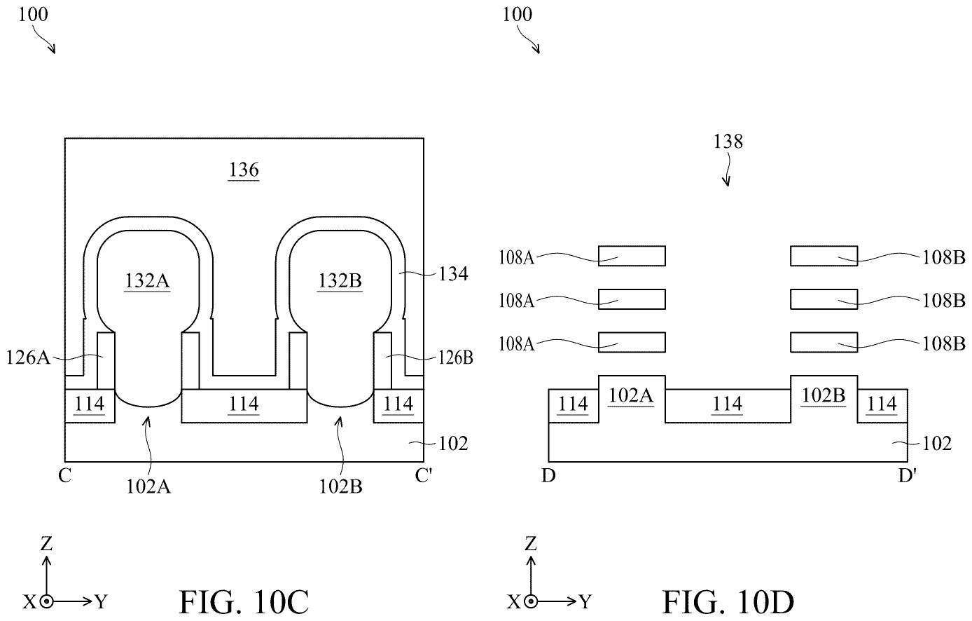

Referring to FIGS. 10A to 10D, the dummy gate structure 116 is selectively removed through any suitable photolithography and etching processes, in accordance with some embodiments. In some embodiments, the photolithography process may include forming a photoresist layer, exposing the photoresist to a pattern, performing a post-exposure bake process, and developing the photoresist to form a masking element, which exposes a region including the dummy gate structure 116. Then, the dummy gate structure 116 is selectively etched through the masking element. The gate spacers 124 may be used as the masking element or a part thereof. Etch selectivity may be achieved by selecting appropriate etching chemicals, and the dummy gate structure 116 may be removed without substantially affecting the CESLs 134 and the ILD layers 136. The removal of the dummy gate structure 116 creates a gate trench 138, as shown in FIGS. 10A to 10D. In some embodiments, the gate trench 138 exposes the top surfaces of the topmost semiconductor layers 108A and 108B that underlie the dummy gate structure 116.

Still referring to FIGS. 10A to 10D, the semiconductor layers 106A and 106B are selectively removed through the gate trench 138, using a wet or dry etching process for example, in accordance with some embodiments. After the semiconductor layers 106A and 106B are selectively removed, the semiconductor layers 108A and 108B are exposed in the gate trench 138 to form the nanostructures stacked on top of each other. As such, the semiconductor layers 108A and 108B may be referred to as nanostructures. Such a process may also be referred to as a wire/nanowire/nanosheet release process, or a wire/nanowire/nanosheet formation process.

In some embodiments, the semiconductor layers 108A are stacked over and spaced apart from each other in the Z-direction, and the semiconductor layers 108B are stacked over and spaced apart from each other in the Z-direction. More specifically, the semiconductor layers 108A are suspended over, and vertically arranged over, the base fin 102A of the substrate 102 in the Z-direction and constitute a vertical stack, and the semiconductor layers 108B are suspended over, and vertically arranged over, the base fin 102B of the substrate 102 in the Z-direction and constitute a vertical stack.

In some embodiments, portions of the semiconductor layers 108 exposed in the gate trench 138 may be partially etched during the removal of the semiconductor layers 106. For example, each of the semiconductor layers 108A and 108B may include end portions covered by the inner spacers 130 and the gate spacers 124, and include a middle portion between the end portions and exposed by the gate trench 138. The middle portions exposed in the gate trench 138 may be partially etched during the removal of the semiconductor layers 106A and 106B, so that the end portions have greater thickness than the middle portion. For example, after the removal of the semiconductor layers 106A and 106B, each of the semiconductor layers 108A and 108B may have a dumbbell shape (or dog-bone shape).

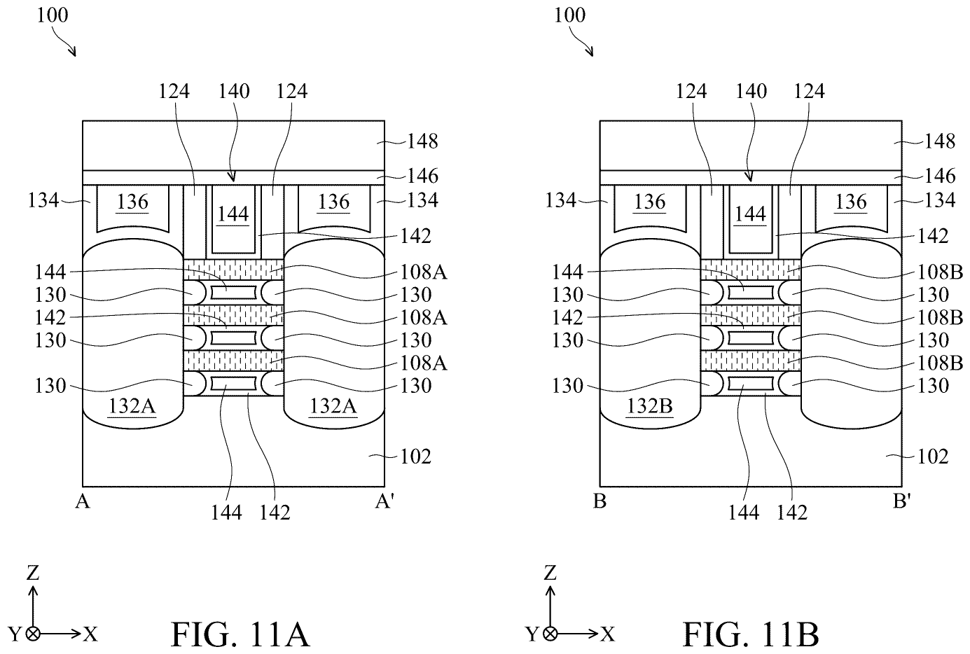

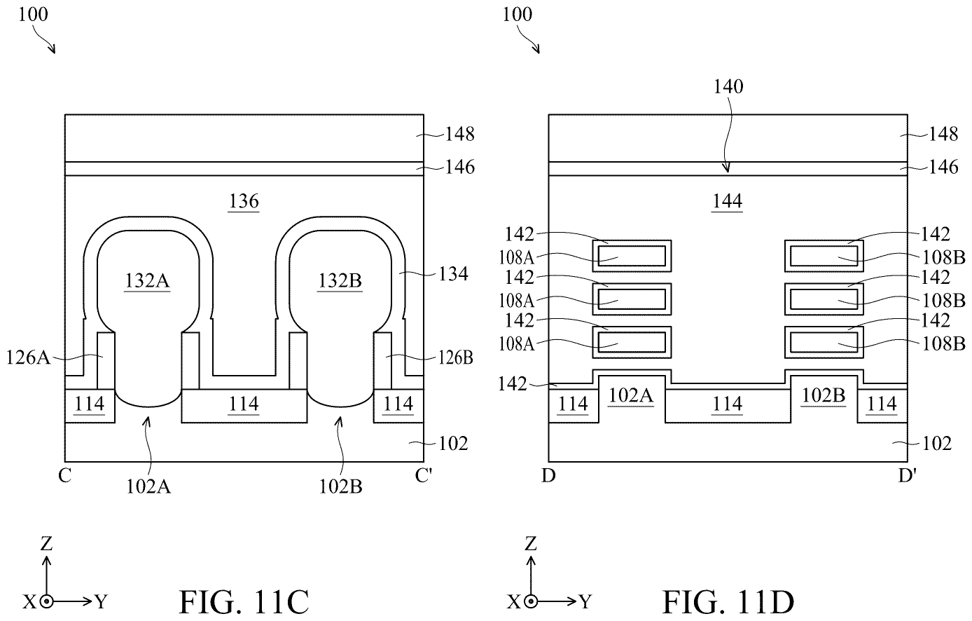

Referring to FIGS. 11A to 11D, a gate structure 140 is formed in the gate trench 138 to wrap around each of the exposed semiconductor layers 108A and 108B, respectively, in accordance with some embodiments. As such, the gate structure 140 replace the dummy gate structure 116. In some embodiments, the gate structure 140 extend in the Y-direction. In some embodiments, the source/drain features 132A are formed on opposite sides of the gate structure 140 in the X-direction, as shown in FIG. 11A. In some embodiments, the source/drain features 132B are formed on opposite sides of the gate structure 140 in the X-direction, as shown in FIG. 11B.

In some embodiments, the gate structure 140 includes a gate dielectric layer 142 and a gate electrode layer 144 over the gate dielectric layer 142. In some embodiments, the gate dielectric layer 142 are formed to wrap around semiconductor layers 108A and 108B in the gate trench 138. In some embodiments, the gate dielectric layers 142 are also formed on the sidewalls of the inner spacers 130 and the gate spacers 124, and over the top surfaces of the isolation structures 114 and the base fins 102A and 102B.

In some embodiments, the gate dielectric layer 142 may include a dielectric material, such as SiOCN, SiOC, SiCN, SiO₂, SiN, SiC, or other suitable materials. In some embodiments, the gate dielectric layer 142 includes a high-k dielectric material that has a dielectric constant greater than a dielectric constant of SiO₂, which is approximately 3.9. For example, the gate dielectric layer 142 may include hafnium oxide (HfO₂), which has a dielectric constant that is in a range from about 18 to about 40. Alternatively, the gate dielectric layer 142 may include other high-k dielectrics, such as TiO₂, HfZrO, Ta₂O₃, HfSiO4, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, SiN, SiON, a combination thereof, or another suitable material. The gate dielectric layer 142 may be formed by CVD, PVD, ALD, HDPCVD, MOCVD, RPCVD, PECVD, LPCVD, ALCVD, APCVD, FCVD, oxidation, and/or other suitable methods.

In some embodiments, the gate structure 140 may further include an interfacial layer (not shown) that is formed to wrap around the exposed semiconductor layers 108A and 108B before forming the gate dielectric layer 142, so that the gate dielectric layer 142 is separated from the semiconductor layers 108A and 108B by the interfacial layer. In some embodiments, the interfacial layer may include a dielectric material such as SiO₂, HfSiO, or SiON. The interfacial layer may be formed by chemical oxidation, thermal oxidation, CVD, PVD, ALD, HDPCVD, MOCVD, RPCVD, PECVD, LPCVD, ALCVD, APCVD, FCVD, and/or other suitable method.

The gate electrode layer 144 are formed to fill the remaining spaces of the gate trench 138, and over the gate dielectric layer 142 in such a way that the gate electrode layer 144 wraps around the semiconductor layers 108A and 108B, the gate dielectric layer 142, and the interfacial layer (if present). The gate electrode layer 144 may include a single layer or a multi-layer structure. In some embodiments, the gate electrode layer 144 may include a capping layer, a barrier layer, work function metal layers, and/or a fill material. The gate electrode layer 144 may be formed using a deposition process such as CVD, PVD, ALD, HDPCVD, MOCVD, RPCVD, PECVD, LPCVD, ALCVD, APCVD, FCVD, or the like, although any suitable deposition process may be used.

In some embodiments, the capping layer and the barrier layer may include different materials, and may be formed of metallic materials such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

For p-type GAA transistors, the gate electrode layer may include p-type work function metal layers. For n-type GAA transistors, the gate electrode layer may include n-type work function metal layers. The n-type and p-type work function metal layers may include conductive materials tuned to have a desired work function (e.g., an n-type work function or a p-type work function). In some embodiments, the n-type and p-type work function metal layers may include a material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

In some embodiments, the gate structure 140 is divided into a first sub-gate and a second sub-gate. The first sub-gate may be wrapped around the semiconductor layers 108A and disposed between the source/drain features 132A, and the second sub-gate may be wrapped around the semiconductor layers 108B and disposed between the source/drain features 132B. In certain embodiments, the first sub-gate is engaged with the second sub-gate. In other embodiments, an isolation structure is disposed between the first and second sub-gates, so as to electrically separated the first sub-gate from the second sub-gate. In some embodiments, the first sub-gate is used for one of the n-type GAA transistor and the p-type GAA transistor, and the second sub-gate is used for the other one of the n-type GAA transistor and the p-type GAA transistor. In other embodiments, both the first sub-gate and the second sub-gate are used for the same type of GAA transistors (e.g., n-type or p-type).

Still referring to FIGS. 11A to 11D, an etch stop layer (ESL) 146 and an ILD layer 148 are formed over the workpiece 100, in accordance with some embodiments. In some embodiments, the ESL 146 is formed on the gate spacers 124, the CESLs 134, the ILD layers 136, and the gate structure 140, and the ILD layer 148 is formed on the ESL 146, as shown in FIGS. 11A to 11D. In some embodiments, the material and method used in forming the ESL 146 and the ILD layer 148 are the same as or similar to those of the CESLs 134 and the ILD layers 136, respectively, and are not repeated herein.

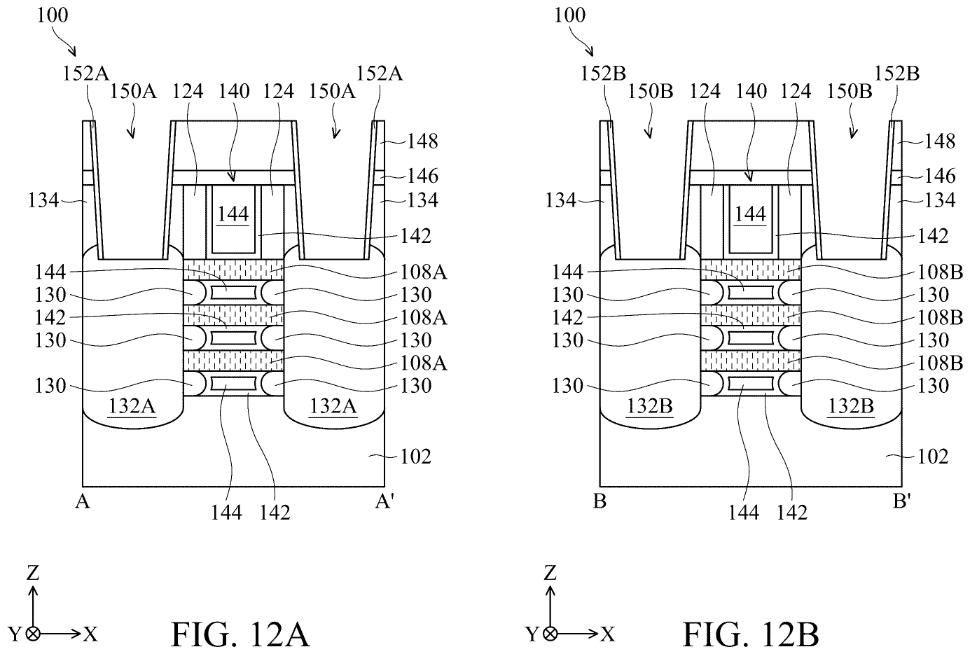

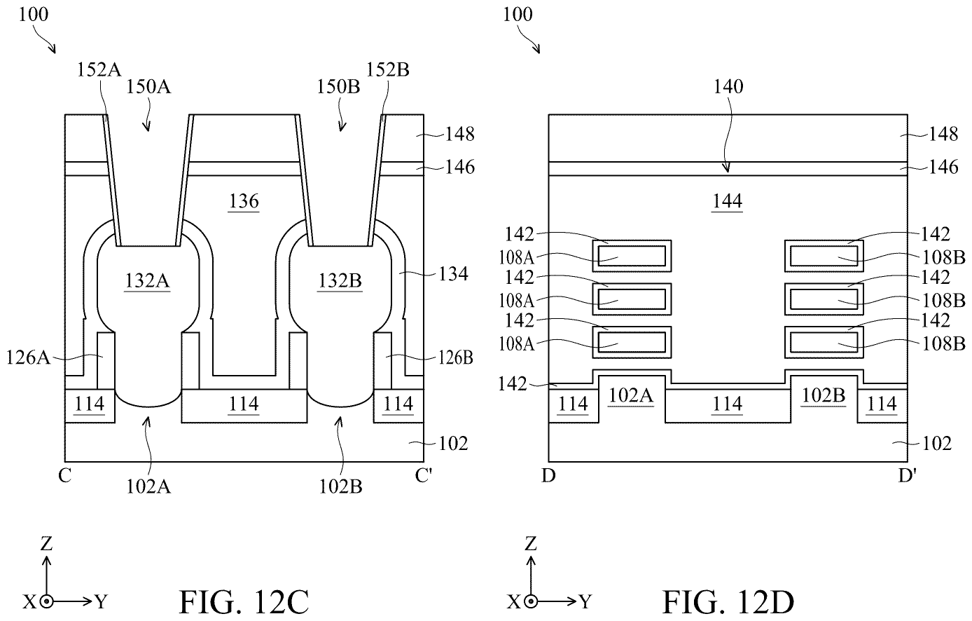

Referring to FIGS. 12A to 12D, trenches for accommodating source/drain contacts are formed to expose the source/drain features 132A and 132B, in accordance with some embodiments. In some embodiments, trenches 150A are formed to pass through the ILD layer 148, the ESL 146, the ILD layers 136, the CESLs 134, and portions of the source/drain features 132A, so as to expose the source/drain features 132A. In some embodiments, trenches 150B are formed to pass through the ILD layer 148, the ESL 146, the ILD layers 136, the CESLs 134, and portions of the source/drain features 132B, so as to expose the source/drain features 132B.

In some embodiments, one or more photolithography and etching processes are performed to etch the ILD layer 148, the ESL 146, the ILD layers 136, and the CESLs 134, and partially etch the source/drain features 132A and 132B, so as to form the trenches 150A that expose the source/drain features 132A and form the trenches 150B that expose the source/drain features 132B. In some embodiments, the bottom surfaces of the trenches 150A are higher than the bottom surface of the topmost semiconductor layer 108A. In further embodiments, the bottom surfaces of the trenches 150A are higher than the top surface of the topmost semiconductor layer 108A. In some embodiments, the bottom surfaces of the trenches 150B are higher than the bottom surface of the topmost semiconductor layer 108B. In further embodiments, the bottom surfaces of the trenches 150B are higher than the top surface of the topmost semiconductor layer 108B.

Still referring to FIGS. 12A to 12D, sidewall dielectric layers 152A and 152B are formed on sidewalls of the trenches 150A and 150B, respectively, in accordance with some embodiments. In other words, the sidewall dielectric layers 152A are formed on surfaces of the ILD layer 148, the ESL 146, the ILD layers 136, the CESLs 134, and the source/drain features 132A that form the sidewalls of the trenches 150A, while bottoms of the trenches 150A still expose the source/drain features 132A. Similarly, the sidewall dielectric layers 152B are formed on surfaces of the ILD layer 148, the ESL 146, the ILD layers 136, the CESLs 134, and the source/drain features 132B that form the sidewalls of the trenches 150B, while bottoms of the trenches 150B still expose the source/drain features 132B. In some embodiments, the material of the sidewall dielectric layers 152A and 152B may include SiN, SiO₂, SiC, SiOC, SiON, SiCN, SiOCN, high-k dielectrics, other suitable materials, or combinations thereof.

In some embodiments, the sidewall dielectric layers 152A and 152B may be formed by conformally depositing a material layer (containing dielectric material) on the surfaces of the ILD layer 148 and the trenches 150A and 150B. An anisotropic etching process is then performed to remove horizontal portions of the material layer from the top surface of the ILD layer 148 and the bottom surfaces of the trenches 150A and 150B. After the anisotropic etching process, the portions of the material layer on the sidewall surfaces of trenches 150A and 150B remain and become the sidewall dielectric layers 152A and 152B, and the horizontal surfaces of source/drain features 132A and 132B are still exposed by the trenches 150A and 150B, respectively. In some embodiments, the anisotropic etching process is a dry (e.g., plasma) etching process. Additionally or alternatively, the formation of the sidewall dielectric layers 152A and 152B may also involve chemical oxidation, thermal oxidation, CVD, PVD, ALD, HDPCVD, MOCVD, RPCVD, RECVD, PECVD, LPCVD, ALCVD, APCVD, FCVD, and/or other suitable methods.

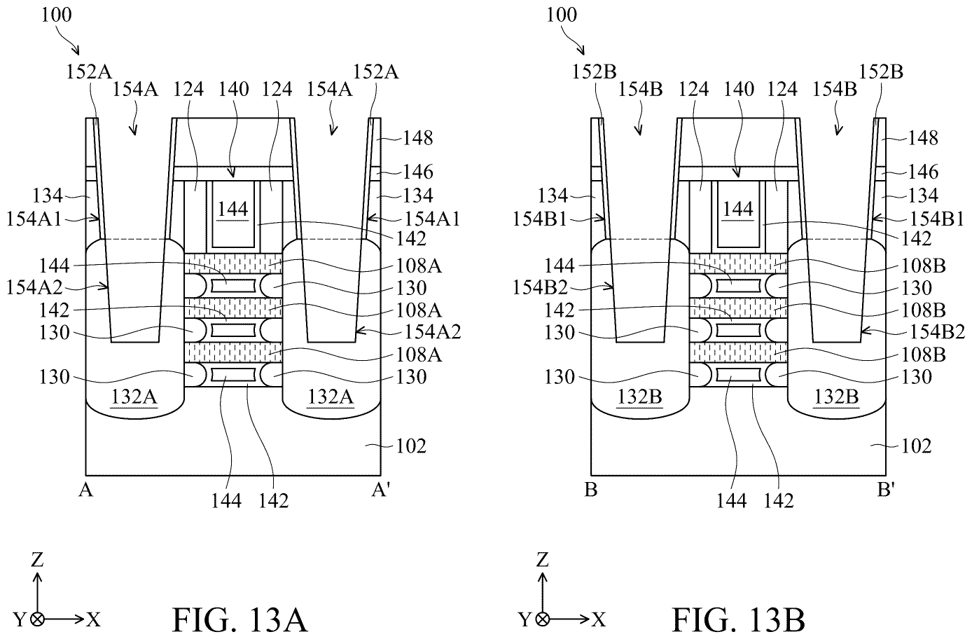

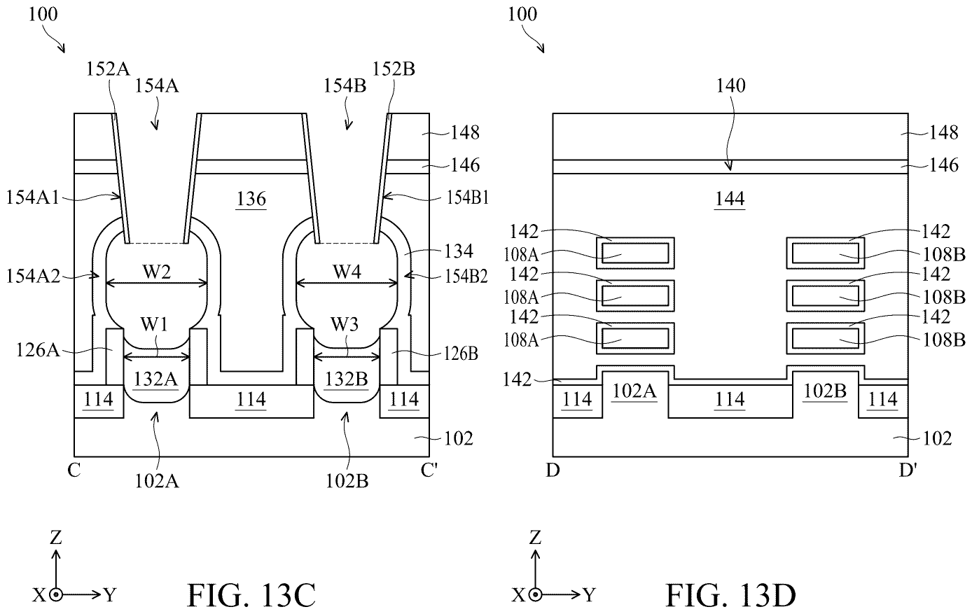

Referring to FIGS. 13A to 13D, the trenches 150A and the trenches 150B are extended to form contact trenches 154A and contact trenches 154B, respectively, in accordance with some embodiments. In some embodiments, the source/drain features 132A and 132B are partially etched to further extend the trenches 150A and 150B downward in the Z-direction. After etching, the extended trenches 150A and 150B can be referred to as contact trenches 154A and 154B, respectively. In some embodiments, the bottom surfaces of the contact trenches 154A are lower than the second bottommost semiconductor layer 108A. For example, the bottom surfaces of the contact trenches 154A are lower than the top surface of the second bottommost semiconductor layer 108A and higher than the bottom surface of the bottommost semiconductor layer 108A. In some embodiments, the bottom surfaces of the contact trenches 154B are lower than the second bottommost semiconductor layer 108B. For example, the bottom surfaces of the contact trenches 154B are lower than the top surface of the second bottommost semiconductor layer 108B and higher than the bottom surface of the bottommost semiconductor layer 108B.

In some embodiments, the trenches 150A and 150B are extended by one or more etching processes. The etching processes may be selective etching processes that selectively etch the source/drain features 132A and 132B, with minimal etching (or substantially no etching) of the ILD layer 148 and the sidewall dielectric layers 152A and 152B. The selective etching process may be a dry etching process, a wet etching process, other suitable etching process, or combinations thereof. The selective etching process may also be an anisotropic etching process.

In some embodiments, the etching process is a dry (e.g., plasma) etching process that is anisotropic and selectively etches the source/drain features 132A and 132B, with minimal etching (or substantially no etching) of the sidewall dielectric layers 152A and 152B, the ILD layer 148, the ESL 146, the ILD layers 136, the CESLs 134, the gate spacers 124, and the side spacers 126A and 126B. In some embodiments, the dry etching process utilizes an etchant and a protection gas. For example, the etchant may include one or more of Cl₂, BCl₂, CF₄, and other suitable etchants, and the protection gas may include one or more of O₂, N₂, He, Ar, BCl₃, and other suitable protection gases. In some embodiments, the flow rate of the etchant and the flow rate of the protection gas are configured to control shapes of the lower portions (e.g., the lower portions 154A2 and 154B2 described below) of the contact trenches 154A and 154B. For example, in the X-direction and Y-direction, the widths of bottoms of the contact trenches 154A and 154B may be wider by flowing the protection gas at a lower flow rate, such that the shapes of the lower portions are similar to a trapezoid shape. For example, in the X-direction and Y-direction, the widths of bottoms of the contact trenches 154A and 154B may be narrower by flowing the protection gas at a higher flow rate, such that the shapes of the lower portions are similar to an awl-shape or a cone-shape. In some embodiments, regarding the trapezoid shape, the ratio of short base to long base is greater than 0.5; and regarding the awl-shape, the ratio of short base to long base is smaller than 0.5. In some embodiments, the dry etching process is performed for about 1 second to about 30 second, at a temperature in the range of about 200° C. to about 500° C., and at a pressure in the range of about 1 mTorr (millitorr) to about 40 mTorr.

In some embodiments, the contact trenches 154A include upper portions 154A1 formed from the trenches 150A and lower portions 154A2 formed by extending the trenches 150A. Similarly, in some embodiments, the contact trenches 154B include upper portions 154B1 formed from the trenches 150B and lower portions 154B2 formed by extending the trenches 150B. In some embodiments, the upper portions 154A1 are surrounded by the sidewall dielectric layers 152A, and the lower portions 154A2 expose the source/drain features 132A. In further embodiments, the lower portions 154A2 expose the CESLs 134 and are surrounded by the CESLs 134, as shown in FIG. 13C. In some embodiments, the lower portions 154A2 have the width W2 in the Y-direction. In some embodiments, the upper portions 154B1 are surrounded by the sidewall dielectric layers 152B, and the lower portions 154B2 expose the source/drain features 132B. In further embodiments, the lower portions 154B2 expose the CESLs 134 and are surrounded by the CESLs 134, as shown in FIG. 13C. In some embodiments, the lower portions 154B2 have the width W4 in the Y-direction.

In some embodiments, the side spacers 126A are exposed by the lower portions 154A2 of the contact trenches 154A, as shown in FIG. 13C. In some embodiments, the side spacers 126B are exposed by the lower portions 154B2 of the contact trenches 154B, as shown in FIG. 13C. In some embodiments, portions of the sidewall dielectric layers 152A are suspended in the lower portions 154A2 of the contact trenches 154A, as shown in FIG. 13C. In some embodiments, portions of the sidewall dielectric layers 152B are suspended in the lower portions 154B2 of the contact trenches 154B, as shown in FIG. 13C. In some embodiments, the remaining portions of the source/drain features 132A have the width W1 in the Y-direction and between the side spacers 126A. In some embodiments, the remaining portions of the source/drain features 132B have the width W3 in the Y-direction and between the side spacers 126B.

In some embodiments, after the formation of the contact trenches 154A and 154B, a cleaning process is performed to clean surfaces of the workpiece 100. The cleaning process may include a dry clean, a wet clean, or a combination thereof. In some embodiments, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), or hydrofluoric acid for oxide removal. The dry clean process may include helium (He) and hydrogen (H₂) treatment. The hydrogen treatment may convert silicon on the surface to silane (SiH₄), which may be pumped out for removal.

In some embodiments, an optional doping process is performed to dope p-type dopant (e.g., B or In) into p-type source/drain features, so as to increase the p-type doping concentration in the p-type source/drain features. In some embodiments, the p-type dopant may be doped by using ion implantation or thermal diffusion.

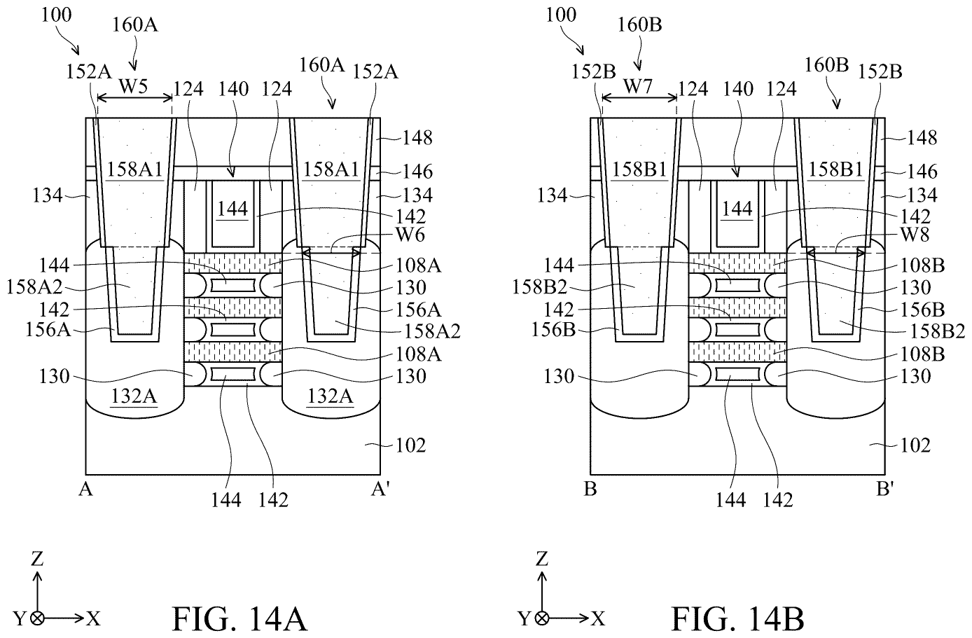

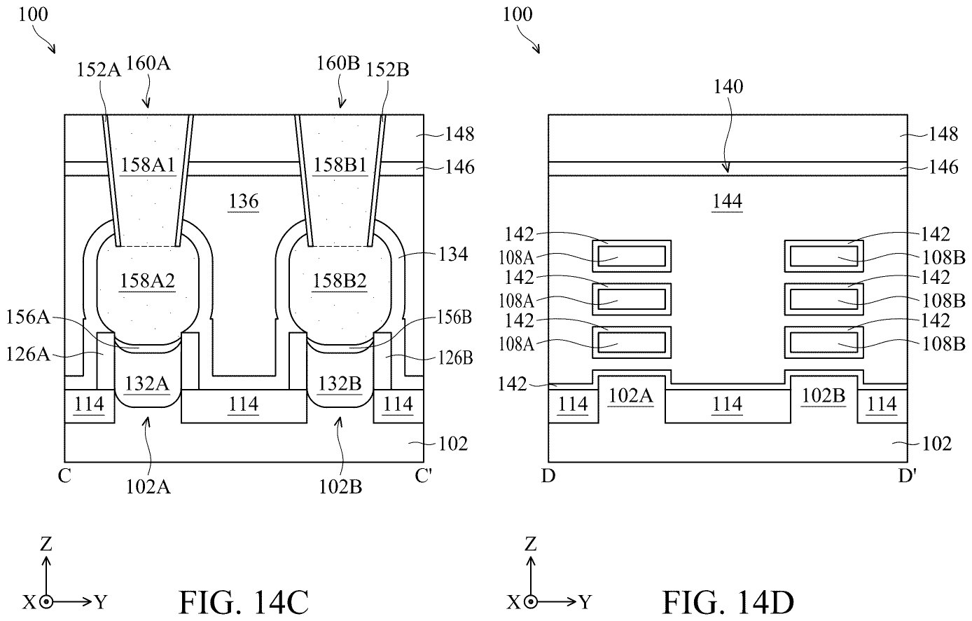

Referring to FIGS. 14A to 14D, source/drain contacts 160A and source/drain contacts 160B are formed in the contact trenches 154A and the contact trenches 154B, respectively, in accordance with some embodiments. In some embodiments, silicide layers 156A are formed on the exposed surfaces of the source/drain features 132A in the contact trenches 154A, and silicide layers 156B are formed on the exposed surfaces of the source/drain features 132B in the contact trenches 154B. In some embodiments, metal portions 158A are formed on the silicide layers 156A and in the contact trenches 154A, and metal portions 158B are formed on the silicide layers 156B and in the contact trenches 154B. The source/drain contacts 160A may each include the silicide layer 156A and the metal portion 158A, and the source/drain contacts 160B may each include the silicide layer 156B and the metal portion 158B.

In some embodiments, the bottom surfaces of the source/drain contacts 160A are lower than the second bottommost semiconductor layer 108A. For example, the bottom surfaces of the source/drain contacts 160A are lower than the top surface of the second bottommost semiconductor layer 108A and higher than the bottom surface of the bottommost semiconductor layer 108A. In some embodiments, the bottom surfaces of the source/drain contacts 160B are lower than the second bottommost semiconductor layer 108B. For example, the bottom surfaces of the source/drain contacts 160B are lower than the top surface of the second bottommost semiconductor layer 108B and higher than the bottom surface of the bottommost semiconductor layer 108B.

In some embodiments, the silicide layers 156A are formed by depositing metal layers on the source/drain features 132A, and heating the workpiece 100 to cause constituents of the source/drain features 132A to react with metal constituents of the metal layers. Similarly, the silicide layers 156B may be formed by depositing metal layers on the source/drain features 132B, and heating the workpiece 100 to cause constituents of the source/drain features 132B to react with metal constituents of the metal layers. In some embodiments, the silicide layers 156A and 156B may include TiSi, NiSi, WSi, NiPtSi, NiPtGeSi, NiGeSi, YbSi, PtSi, IrSi, ErSi, CoSi, or other suitable compounds.

In some embodiments, a conductive material is deposited in the contact trenches 154A and 154B and on the silicide layers 156A and 156B by a deposition process, so as to form the metal portions 158A and 158B of the source/drain contacts 160A and 160B. That is, the contact trenches 154A are filled with the conductive material to form the source/drain contacts 160A, and the contact trenches 154B are filled with the conductive material to form the source/drain contacts 160B. The conductive material may include Al, Cu, W, Co, Ti, Ta, Ru, Rh, Ir, Pt, TiN, TiAl, TiAlN, TaN, TaC, combinations thereof, or the like, although any suitable material may be used. The conductive material may be deposited using a deposition process such as sputtering, CVD, PVD, ALD, HDPCVD, MOCVD, RPCVD, PECVD, LPCVD, ALCVD, APCVD, FCVD, and/or other suitable method.

In some embodiments, the metal portions 158A of the source/drain contacts 160A include upper portions 158A1 formed in the upper portions 154A1 of the contact trenches 154A, and include lower portions 158A2 formed in the lower portions 154A2 of the contact trenches 154A. In some embodiments, the metal portions 158B of the source/drain contacts 160B include upper portions 158B1 formed in the upper portions 154B1 of the contact trenches 154B, and include lower portions 158B2 formed in the lower portions 154B2 of the contact trenches 154B. In some embodiments, the upper portions 158A1 of the metal portions 158A are adjacent to the sidewall dielectric layers 152A. In further embodiments, the upper portions 158A1 of the metal portions 158A are surrounded by the sidewall dielectric layers 152A. In some embodiments, the upper portions 158B1 of the metal portions 158B are adjacent to the sidewall dielectric layers 152B. In further embodiments, the upper portions 158B1 of the metal portions 158B are surrounded by the sidewall dielectric layers 152B.

In some embodiments, the lower portions 158A2 of the metal portions 158A are formed on the silicide layers 156A. In further embodiments, the lower portions 158A2 are surrounded by the silicide layers 156A in an X-Z plane, as shown in FIG. 14A. In some embodiments, the lower portions 158A2 are adjacent to the CESLs 134. In further embodiments, the lower portions 158A2 are surrounded by the CESLs 134 in a Y-Z plane, as shown in FIG. 14C. In some embodiments, the silicide layers 156A are adjacent to or in partial contact with the side spacers 126A, as shown in FIG. 14C. In further embodiments, the lower portions 158A2 of the metal portions 158A are adjacent to or in partial contact with the side spacers 126A in the Y-Z plane shown in FIG. 14C.

In some embodiments, the lower portions 158B2 of the metal portions 158B are formed on the silicide layers 156B. In further embodiments, the lower portions 158B2 are surrounded by the silicide layers 156B in an X-Z plane, as shown in FIG. 14B. In some embodiments, the lower portions 158B2 are adjacent to the CESLs 134. In further embodiments, the lower portions 158B2 are surrounded by the CESLs 134 in the Y-Z plane, as shown in FIG. 14C. In some embodiments, the silicide layers 156B are adjacent to or in partial contact with the side spacers 126B, as shown in FIG. 14C. In further embodiments, the lower portions 158B2 of the metal portions 158B are adjacent to or in partial contact with the side spacers 126B in the Y-Z plane shown in FIG. 14C.

In some embodiments, the workpiece 100 has a critical poly pitch (CPP) in a range from about 48 nm to about 54 nm. For example, the CPP may be defined as a distance between the middle line of the gate structure 140 and the middle line of the adjacent gate structure 140, or a distance between the middle line of the source/drain feature 132A/132B and the middle line of the adjacent source/drain feature 132A/132B. In these embodiments, the top surfaces of the source/drain contacts 160A have a width W5 in the X-direction. In some embodiments, the width W5 is in a range from about 11 nm to about 15 nm, for example, in a range from about 12 nm to about 14 nm. In some embodiments, in the level aligned with the top surface of the topmost semiconductor layer 108A, the source/drain contacts 160A have a width W6 in the X-direction. In some embodiments, the width W6 is in a range from about 10.5 nm to about 14.5 nm, for example, in a range from about 11.5 nm to about 13.5 nm.

In some embodiments, in the level below the top surface of the topmost semiconductor layer 108A by 5 nm in Z-direction, the source/drain contacts 160A have a width in the X-direction that is in a range from about 10 nm to about 14 nm, for example, in a range from about 11 nm to about 13 nm. In some embodiments, in the level below the top surface of the topmost semiconductor layer 108A by 10 nm in Z-direction, the source/drain contacts 160A have a width in the X-direction that is in a range from about 9 nm to about 13 nm, for example, in a range from about 10 nm to about 12 nm. In some embodiments, in the level below the top surface of the topmost semiconductor layer 108A by 15 nm in the Z-direction, the source/drain contacts 160A have a width in the X-direction that is in a range from about 7 nm to about 11 nm, for example, in a range from about 8 nm to about 10 nm.

Similarly, in the embodiments where the CPP is in a range from about 48 nm to about 54 nm, the top surfaces of the source/drain contacts 160B have a width W7 in the X-direction. In some embodiments, the width W7 is in a range from about 11 nm to about 15 nm, for example, in a range from about 12 nm to about 14 nm. In some embodiments, in the level aligned with the top surface of the topmost semiconductor layer 108B, the source/drain contacts 160B have a width W8 in the X-direction. In some embodiments, the width W8 is in a range from about 10.5 nm to about 14.5 nm, for example, in a range from about 11.5 nm to about 13.5 nm.

In some embodiments, in the level below the top surface of the topmost semiconductor layer 108B by 5 nm in Z-direction, the source/drain contacts 160B have a width in the X-direction that is in a range from about 10 nm to about 14 nm, for example, in a range from about 11 nm to about 13 nm. In some embodiments, in the level below the top surface of the topmost semiconductor layer 108B by 10 nm in Z-direction, the source/drain contacts 160B have a width in the X-direction that is in a range from about 9 nm to about 13 nm, for example, in a range from about 10 nm to about 12 nm. In some embodiments, in the level below the top surface of the topmost semiconductor layer 108B by 15 nm in the Z-direction, the source/drain contacts 160B have a width in the X-direction that is in a range from about 7 nm to about 11 nm, for example, in a range from about 8 nm to about 10 nm.

In some embodiments, the workpiece 100 has a CPP in a range from about 42 nm to about 47 nm. In these embodiments, the width W5 of the source/drain contacts 160A is in a range from about 9 nm to about 14 nm, for example, in a range from about 10 nm to about 13 nm. In some embodiments, in the level aligned with the top surface of the topmost semiconductor layer 108A, the width W6 of the source/drain contacts 160A is in a range from about 8.5 nm to about 13.5 nm, for example, in a range from about 9.5 nm to about 12.5 nm.

In some embodiments, in the level below the top surface of the topmost semiconductor layer 108A by 5 nm in Z-direction, the source/drain contacts 160A have a width in the X-direction that is in a range from about 8 nm to about 13 nm, for example, in a range from about 9 nm to about 12 nm. In some embodiments, in the level below the top surface of the topmost semiconductor layer 108A by 10 nm in Z-direction, the source/drain contacts 160A have a width in the X-direction that is in a range from about 7 nm to about 12 nm, for example, in a range from about 8 nm to about 11 nm. In some embodiments, in the level below the top surface of the topmost semiconductor layer 108A by 15 nm in the Z-direction, the source/drain contacts 160A have a width in the X-direction that is in a range from about 5 nm to about 10 nm, for example, in a range from about 6 nm to about 9 nm.

Similarly, in the embodiments where the CPP is in a range from about 42 nm to about 47 nm, the width W7 of the source/drain contacts 160B is in a range from about 9 nm to about 14 nm, for example, in a range from about 10 nm to about 13 nm. In some embodiments, in the level aligned with the top surface of the topmost semiconductor layer 108B, the width W8 of the source/drain contacts 160B is in a range from about 8.5 nm to about 13.5 nm, for example, in a range from about 9.5 nm to about 12.5 nm.

In some embodiments, in the level below the top surface of the topmost semiconductor layer 108B by 5 nm in Z-direction, the source/drain contacts 160B have a width in the X-direction that is in a range from about 8 nm to about 13 nm, for example, in a range from about 9 nm to about 12 nm. In some embodiments, in the level below the top surface of the topmost semiconductor layer 108B by 10 nm in Z-direction, the source/drain contacts 160B have a width in the X-direction that is in a range from about 7 nm to about 12 nm, for example, in a range from about 8 nm to about 11 nm. In some embodiments, in the level below the top surface of the topmost semiconductor layer 108B by 15 nm in the Z-direction, the source/drain contacts 160B have a width in the X-direction that is in a range from about 5 nm to about 10 nm, for example, in a range from about 6 nm to about 9 nm.

In the embodiments where the workpiece 100 includes three semiconductor layers 108A stacked in the Z-direction, the distance between the level aligned with the top surface of the topmost semiconductor layer 108A and the bottom surface of the source/drain contact 160A (i.e. the height difference between the top surface of the topmost semiconductor layer 108A and the bottom surface of the source/drain contact 160A) is in a range from about 15 nm to about 21 nm (for n-type source/drain features 132A) or in a range from about 14 nm to about 20 nm (for p-type source/drain features 132A). In the embodiments where the workpiece 100 includes two semiconductor layers 108A stacked in the Z-direction, the distance between the level aligned with the top surface of the topmost semiconductor layer 108A and the bottom surface of the source/drain contact 160A is in a range from about 11 nm to about 17 nm (for n-type source/drain features 132A) or in a range from about 10 nm to about 16 nm (for p-type source/drain features 132A). In the embodiments where the workpiece 100 includes four semiconductor layers 108A stacked in the Z-direction, the distance between the level aligned with the top surface of the topmost semiconductor layer 108A and the bottom surface of the source/drain contact 160A is in a range from about 27 nm to about 34 nm (for n-type source/drain features 132A) or in a range from about 28 nm to about 35 nm (for p-type source/drain features 132A).

In the embodiments where the workpiece 100 includes three semiconductor layers 108B stacked in the Z-direction, the distance between the level aligned with the top surface of the topmost semiconductor layer 108B and the bottom surface of the source/drain contact 160B is in a range from about 15 nm to about 21 nm (for n-type source/drain features 132B) or in a range from about 14 nm to about 20 nm (for p-type source/drain features 132B). In the embodiments where the workpiece 100 includes two semiconductor layers 108B stacked in the Z-direction, the distance between the level aligned with the top surface of the topmost semiconductor layer 108B and the bottom surface of the source/drain contact 160B is in a range from about 11 nm to about 17 nm (for n-type source/drain features 132B) or in a range from about 10 nm to about 16 nm (for p-type source/drain features 132B). In the embodiments where the workpiece 100 includes four semiconductor layers 108B stacked in the Z-direction, the distance between the level aligned with the top surface of the topmost semiconductor layer 108B and the bottom surface of the source/drain contact 160B is in a range from about 27 nm to about 34 nm (for n-type source/drain features 132B) or in a range from about 28 nm to about 35 nm (for p-type source/drain features 132B).

As described above, the trenches 150A and 150B are extended to form the contact trenches 154A and 154B, so that the (deep) source/drain contacts 160A and 160B formed in the contact trenches 154A and 154B extend into and are partially embedded in the source/drain features 132A and 132B. Therefore, the source/drain contacts 160A and 160B have larger volume to reduce their own bulk resistivity, and provide larger contact area between the source/drain contacts 160A and 160B and the source/drain features 132A and 132B, so as to reduce the contact resistance between the source/drain contacts 160A and 160B and the source/drain features 132A and 132B.

Moreover, the process described herein can maintain the critical dimensions of the source/drain contacts 160A and 160B since the selective etching process is utilized, can control the depths of the source/drain contacts 160A and 160B by controlling the process duration, and can control the shapes of the source/drain contacts 160A and 160B by controlling the flowing rates of the etchant and the protection gas. Therefore, the process described herein provides a process flexibility for forming the source/drain contacts 160A and 160B. For example, the depths of the source/drain contacts 160A and 160B can be controlled according to the number of the semiconductor layers 108A/108B stacked over the substrate. For example, the source/drain contacts 160A and 160B can be formed deeper when the number of the semiconductor layers 108A/108B is larger, and the source/drain contacts 160A and 160B can be formed shallower when the number of the semiconductor layers 108A/108B is smaller. As such, the source/drain contacts 160A and 160B can be closer to the bottommost semiconductor layer 108A/108B, so as to mitigate the current crowding effect.

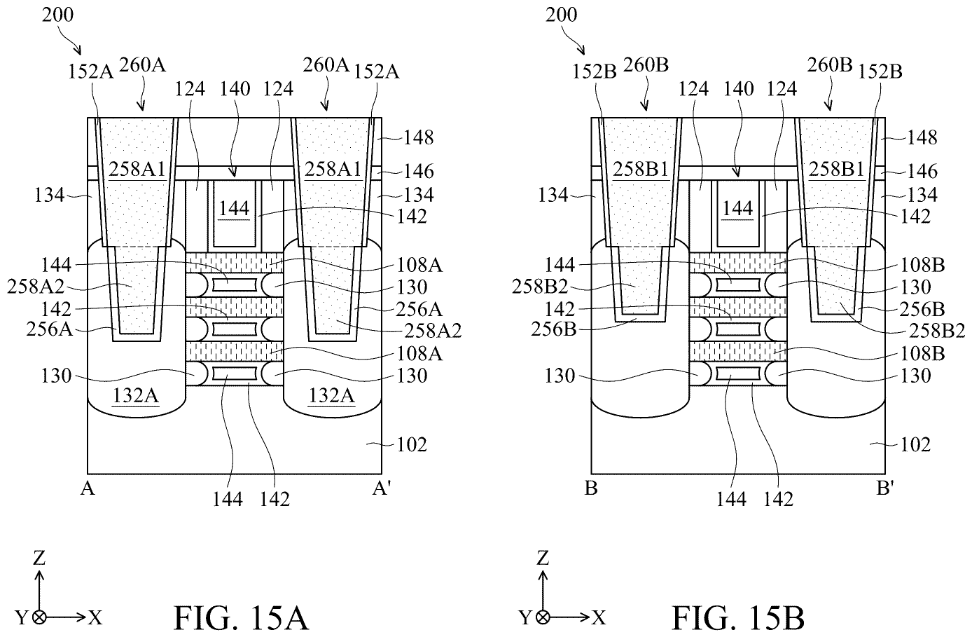

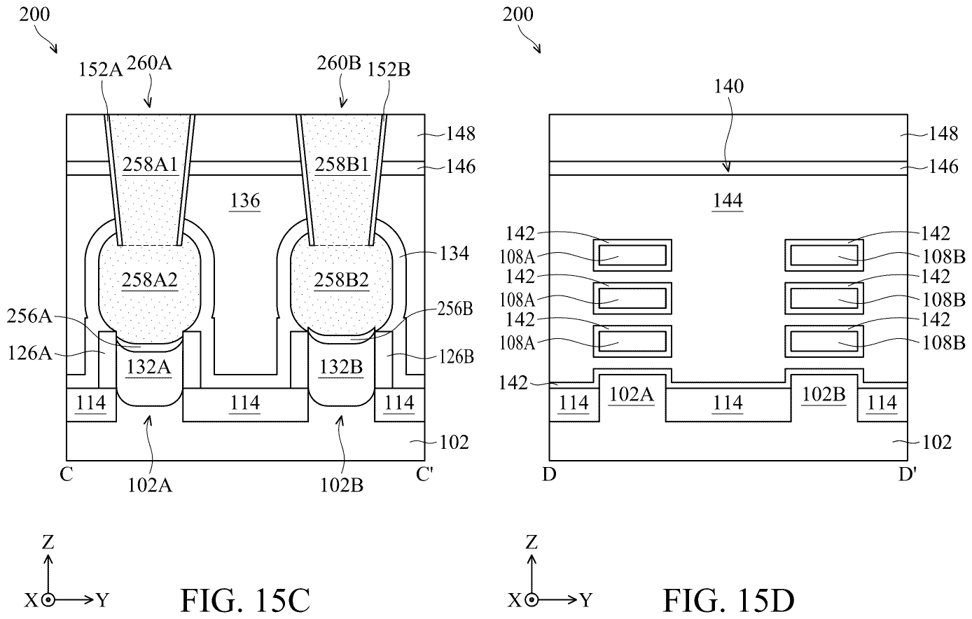

FIGS. 15A and 15B are X-Z cross-sectional views of a semiconductor structure 200 along lines A-A′ and B-B′ of FIG. 4, respectively, in accordance with some embodiments. FIGS. 15C and 15D are Y-Z cross-sectional views of the semiconductor structure 200 along lines C-C′ and D-D′ of FIG. 4, respectively, in accordance with some embodiments. The semiconductor structure 200 shown in FIGS. 15A to 15D may be similar to the semiconductor structure 100 shown in FIGS. 14A to 14D, except the source/drain contacts 160A and 160B are replaced by the source/drain contacts 260A and 260B, respectively.

In some embodiments, the source/drain contacts 260A each includes a silicide layer 256A and a metal portion 258A, and the source/drain contacts 160B each includes a silicide layer 256B and a metal portion 258B. In some embodiments, the metal portions 258A of the source/drain contacts 260A include lower portions 258A2 and upper portions 258A1 over the lower portions 258A2. In some embodiments, the metal portions 258B of the source/drain contacts 260B include lower portions 258B2 and upper portions 258B1 formed over the lower portions 258B2. In some embodiments, the upper portions 258A1 of the metal portions 258A are surrounded by the sidewall dielectric layers 152A. In some embodiments, the upper portions 258B1 of the metal portions 258B are surrounded by the sidewall dielectric layers 152B.

In some embodiments, the depths of the source/drain contacts 260B are less than the depths of the source/drain contacts 260A. That is, the bottom surfaces of the source/drain contacts 260B are higher than the bottom surfaces of the source/drain contacts 260A in the Z-direction, as shown in FIGS. 15A to 15B. In these embodiments, the volumes of the source/drain features 132B are greater than that of the source/drain features 132A. In these embodiments, the top surfaces of the source/drain features 132B are higher than the top surfaces of the source/drain features 132A in a Y-Z plane, as shown in FIG. 15C. In further embodiments, the bottom surfaces of the silicide layers 256B are higher than the bottom surfaces of the silicide layers 256A in both X-Z plane and Y-Z plane, as shown in FIGS. 15A to 15C.

In some embodiments, in the X-Z planes shown in FIGS. 15A and 15B, the bottom surfaces of the source/drain contacts 260A are deeper than the bottom surfaces of the source/drain contacts 260B by a range from about 0 nm to about 4 nm, for example, by a range from about 0.5 nm to about 4 nm. In some embodiments, in the Y-Z plane shown in FIG. 15C, the top surfaces of the source/drain features 132B are higher than the top surfaces of the source/drain features 132A by a range from about 0 nm to about 4 nm, for example, by a range from about 0.5 nm to about 4 nm.

In some embodiments, the difference between the source/drain contacts 260A and 260B shown in FIGS. 15A to 15D may be achieved by modifying the parameters of the etching process described above with reference to FIGS. 13A to 13C. For example, the etchant of the etching process may be configured to cause the source/drain features 132A to be etched faster than the source/drain features 132B. In this way, the depths of the contact trenches 154A are greater than the depths of the contact trenches 154B. As a result, the source/drain contacts 260B formed in the source/drain features 132B will be shallower than the source/drain contacts 260A formed in the source/drain features 132A.

In some embodiments, the etching process utilizes an etchant and a protection gas. For example, the etchant may include one or more of Cl₂, BCl₂, CF₄, and other suitable etchants, and the protection gas may include one or more of O₂, N₂, He, Ar, BCl₃, and other suitable protection gases. In some embodiments, the flow rate of the etchant and the flow rate of the protection gas are configured to control shapes of the lower portions 154A2 and 154B2 of the contact trenches 154A and 154B. In some embodiments, the etching process is performed for about 1 second to about 30 second, at a temperature in the range of about 200° C. to about 500° C., and at a pressure in the range of about 1 mTorr (millitorr) to about 40 mTorr.

In some embodiments, the lower portions 258A2 of the metal portions 258A are formed on the silicide layers 256A. In further embodiments, the lower portions 258A2 are surrounded by the silicide layers 256A in an X-Z plane, as shown in FIG. 15A. In some embodiments, the lower portions 258A2 are surrounded by the CESLs 134 in a Y-Z plane, as shown in FIG. 15C. In some embodiments, the silicide layers 256A are attached to or in partial contact with the side spacers 126A, as shown in FIG. 15C. In further embodiments, the lower portions 258A2 of the metal portions 258A are attached to or in partial contact with the side spacers 126A in the Y-Z plane shown in FIG. 15C.

In some embodiments, the lower portions 258B2 of the metal portions 258B are formed on the silicide layers 256B. In further embodiments, the lower portions 258B2 are surrounded by the silicide layers 256B in an X-Z plane, as shown in FIG. 15B. In some embodiments, the lower portions 258B2 are surrounded by the CESLs 134 in the Y-Z plane, as shown in FIG. 15C. In some embodiments, the silicide layers 256B are separated from the side spacers 126B by the source/drain features 132B and the CESLs 134, and the lower portions 258B2 are separated from the side spacers 126B by the source/drain features 132B, the CESLs 134, and the silicide layers 256B, as shown in FIG. 15C. In other embodiments, the silicide layers 256B are attached to or in partial contact with the side spacers 126B, and the lower portions 258B2 are separated from the side spacers 126B by the source/drain features 132B, the CESLs 134, and the silicide layers 256B.

In some embodiments, the source/drain features 132A are n-type source/drain features for an n-type GAA transistor and the source/drain features 132B are p-type source/drain features for a p-type GAA transistor. In these embodiments, applying the shallower source/drain contacts 260B in the p-type GAA transistor may provide more volume for p-type source/drain features (i.e., the source/drain features 132B). As a result, the channel strain of the p-type GAA transistor can be enhanced, and thus the channel mobility and the DC performance of the p-type GAA transistor are improved. In these embodiments, applying the deeper source/drain contacts 260A in the n-type GAA transistor may provide more contact area between the source/drain contacts and the source/drain features, so as to reduce the contact resistance in the n-type GAA transistor. In other embodiments, the source/drain features 132A are p-type source/drain features for a p-type GAA transistor and the source/drain features 132B are n-type source/drain features for a n-type GAA transistor. In these embodiments, applying the shallower source/drain contacts 260B in the n-type GAA transistor may provide more volume for n-type source/drain features (i.e., the source/drain features 132B).

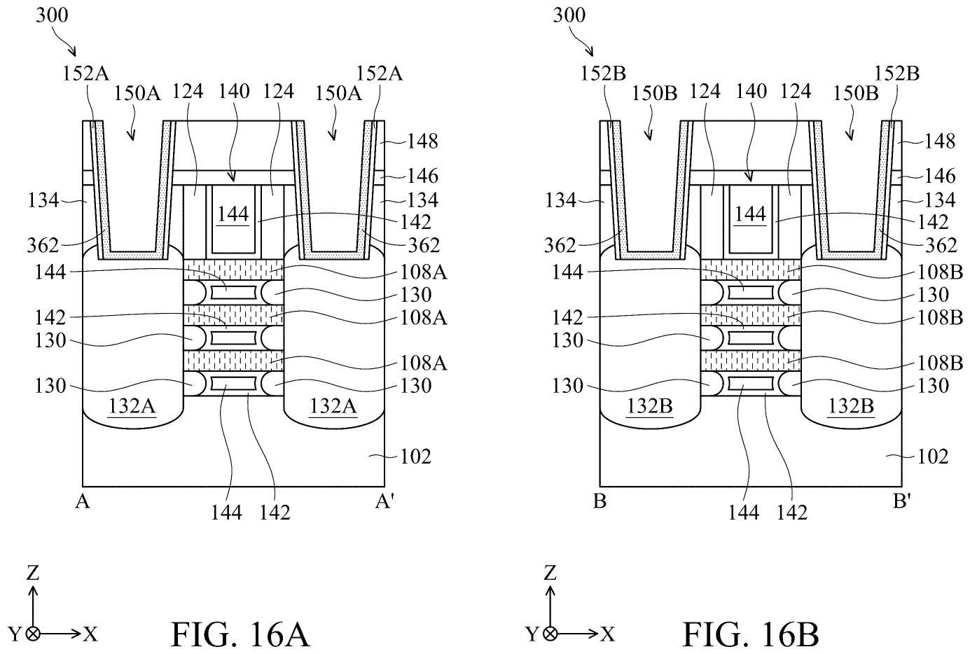

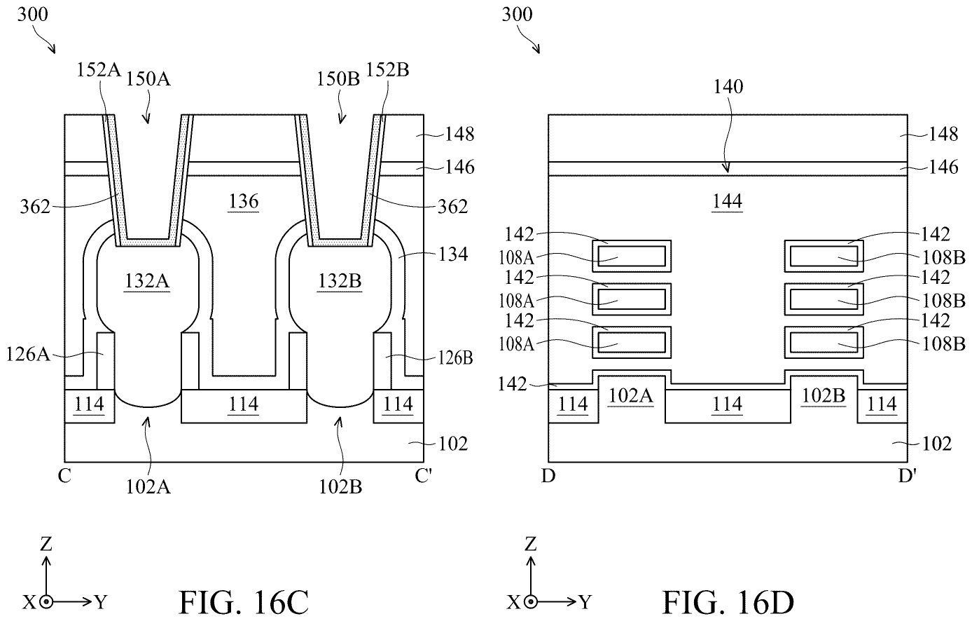

FIGS. 16A, 17A, 19A, 20A, and 21A are X-Z cross-sectional views of the workpiece 300 at various fabrication stages along line A-A′ of FIG. 4, in accordance with some embodiments. FIGS. 16B, 17B, 19B, 20B, and 21B are X-Z cross-sectional views of the workpiece 300 at various fabrication stages along line B-B′ of FIG. 4, in accordance with some embodiments. FIGS. 16C, 17C, 18, 19C, 20C, and 21C are Y-Z cross-sectional views of the workpiece 300 at various fabrication stages along line C-C′ of FIG. 4, in accordance with some embodiments. FIGS. 16D, 17D, 19D, 20D, and 21D are Y-Z cross-sectional views of the workpiece 300 at various fabrication stages along line D-D′ of FIG. 4, in accordance with some embodiments. Since the workpiece 300 will be fabricated into a semiconductor structure 300 upon conclusion of the fabrication processes, the workpiece 300 may be referred to as the semiconductor structure 300 as the context requires.

Referring to FIGS. 16A to 16D, the fabrication stage shown in FIGS. 16A to 16D follows the fabrication stage shown in FIGS. 12A to 12D. In FIGS. 16A to 16D, protection layers 362 are formed in the trenches 150A and 150B, in accordance with some embodiments. In some embodiments, the protection layers 362 are conformally formed in the trenches 150A and 150B. That is, the sidewalls of the sidewall dielectric layers 152A and 152B and the surfaces of the source/drain features 132A and 132B exposed by the trenches 150A and 150B are covered by the protection layers 362. In some embodiments, the top surface of the ILD layers 148 and the sidewall dielectric layers 152A and 152B are also covered by the protection layers 362 (not shown).

The protection layers 362 may include a material that is different than the materials of the sidewall dielectric layers 152A and 152B to achieve desired etching selectivity during the etching process. In some embodiments, the material of the protection layers 362 may include SiN, SiO₂, SiC, SiOC, SiON, SiCN, SiOCN, high-k dielectrics, other suitable materials, or combinations thereof. In some embodiments, the protection layers 362 may be formed by CVD, PVD, ALD, HDPCVD, MOCVD, RPCVD, PECVD, LPCVD, ALCVD, APCVD, FCVD, or other suitable methods.

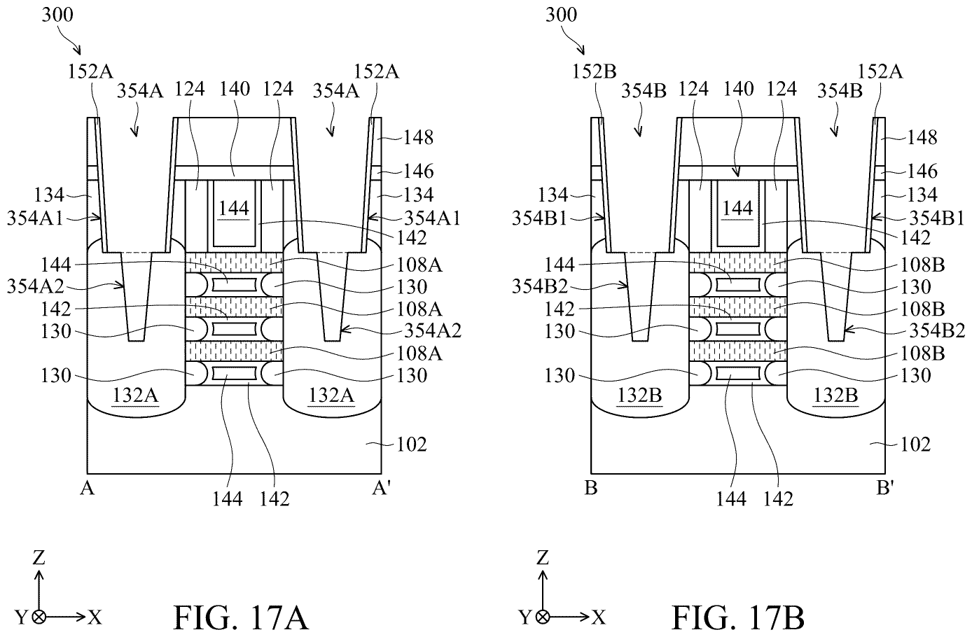

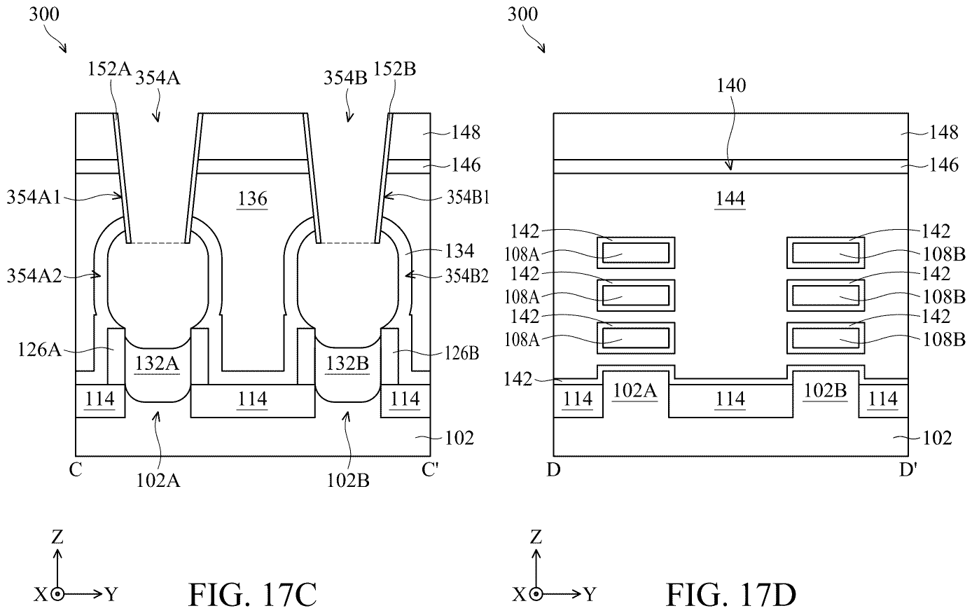

Referring to FIGS. 17A to 17D, the trenches 150A and the trenches 150B are extended to form contact trenches 354A and contact trenches 354B, respectively, in accordance with some embodiments. In some embodiments, the protection layers 362 are etched and the source/drain features 132A and 132B are partially etched to further extend the trenches 150A and 150B downward in the Z-direction. After etching, the extended trenches 150A and 150B can be referred to as contact trenches 354A and 354B, respectively. In some embodiments, the bottom surfaces of the contact trenches 354A are lower than the second bottommost semiconductor layer 108A. For example, the bottom surfaces of the contact trenches 354A are lower than the top surface of the second bottommost semiconductor layer 108A and higher than the bottom surface of the bottommost semiconductor layer 108A. In some embodiments, the bottom surfaces of the contact trenches 354B are lower than the second bottommost semiconductor layer 108B. For example, the bottom surfaces of the contact trenches 354B are lower than the top surface of the second bottommost semiconductor layer 108B and higher than the bottom surface of the bottommost semiconductor layer 108B.

In some embodiments, the trenches 150A and 150B are extended by one or more etching processes. The etching processes may be selective etching processes that selectively etch the source/drain features 132A and 132B and the protection layers 362, with minimal etching (or substantially no etching) of the ILD layer 148 and the sidewall dielectric layers 152A and 152B. The selective etching process may be a dry etching process, a wet etching process, other suitable etching process, or combinations thereof.

In some embodiments, the selective etching process is an anisotropic etching process. In these embodiments, in the Z-direction, the vertical portions of the protection layers 362 formed on the sidewall dielectric layers 152A and 152B have greater effective thickness than the horizontal portions of the protection layers 362 formed on the surfaces of the source/drain features 132A and 132B exposed by the trenches 150A and 150B. Therefore, in the anisotropic etching process, when the horizontal portions are removed and the source/drain features 132A and 132B are exposed, portions of the vertical portions of the protection layers 362 still remain.

Then, the source/drain features 132A and 132B and the remaining vertical portions of the protection layers 362 are etched at the same time. As such, in the trenches 150A and 150B, the central portions of the source/drain features 132A and 132B can be etched more. In this way, the lower portions 354A2 of the contact trenches 354A and the lower portions 354B2 of the contact trenches 354B may be formed to have top surfaces that are narrower than bottom surfaces of the trenches 150A and 150B. Moreover, in this way, the bottom surfaces of the lower portions 354A2 and 354B2 may be formed to be much narrower than the top surfaces, so that the lower portions 354A2 and 354B2 may have an awl-shape or a cone-shape, as shown in FIGS. 17A to 17D. In some embodiments, dimensions of the top surfaces of the lower portions 354A2 and 354B2 can be controlled by the thicknesses of the protection layers 362. For example, the thicker the protection layers 362, the smaller the dimensions of the top surfaces of the lower portions 354A2 and 354B2, and the thinner the protection layers 362, the larger the dimensions of the top surfaces of the lower portions 354A2 and 354B2. In some embodiments, flow rates of the etchant and protection gas during the anisotropic etching process can be modified, so as to assist in controlling shapes of the lower portions 354A2 and 354B2.

In some embodiments, the etching process is a dry (e.g., plasma) etching process that is anisotropic and selectively etch the source/drain features 132A and 132B and the protection layers 362, with minimal etching (or substantially no etching) of the sidewall dielectric layers 152A and 152B, the ILD layer 148, the ESL 146, the ILD layers 136, the CESLs 134, the gate spacers 124, and the side spacers 126A and 126B. In some embodiments, the dry etching process utilizes an etchant and a protection gas. For example, the etchant may include one or more of Cl₂, BCl₂, CF₄, and other suitable etchants, and the protection gas may include one or more of O₂, N₂, He, Ar, BCl₃, and other suitable protection gases. In some embodiments, the flow rate of the etchant and the flow rate of the protection gas are configured to control shapes of the lower portions 354A2 and 354B2 of the contact trenches 354A and 354B. For example, in the X-direction and Y-direction, the widths of bottoms of the contact trenches 354A and 354B may be wider by flowing the protection gas at a lower flow rate. For example, in the X-direction and Y-direction, the widths of bottoms of the contact trenches 354A and 354B may be narrower by flowing the protection gas at a higher flow rate. In some embodiments, the dry etching process is performed for about 1 second to about 30 second, at a temperature in the range of about 200° C. to about 500° C., and at a pressure in the range of about 1 mTorr (millitorr) to about 40 mTorr.

In some embodiments, the contact trenches 354A include upper portions 354A1 formed from the trenches 150A and the lower portions 354A2 formed by extending the trenches 150A. Similarly, in some embodiments, the contact trenches 354B include upper portions 354B1 formed from the trenches 150B and the lower portions 354B2 formed by extending the trenches 150B. In some embodiments, the upper portions 354A1 and 354B1 may have a trapezoid shape, as shown in FIGS. 17A to 17D. In some embodiments, the upper portions 354A1 are surrounded by the sidewall dielectric layers 152A. In further embodiments, the lower portions 354A2 expose the CESLs 134 and are surrounded by the CESLs 134, as shown in FIG. 17C. In some embodiments, the lower portions 354A2 have the width W2 in the Y-direction and between the CESLs 134. In some embodiments, the upper portions 354B1 are surrounded by the sidewall dielectric layers 152B. In further embodiments, the lower portions 354B2 expose the CESLs 134 and are surrounded by the CESLs 134, as shown in FIG. 17C. In some embodiments, the lower portions 354B2 have the width W4 in the Y-direction and between the CESLs 134.

In some embodiments, the side spacers 126A are exposed by the lower portions 354A2 of the contact trenches 354A, as shown in FIG. 17C. In some embodiments, the side spacers 126B are exposed by the lower portions 354B2 of the contact trenches 354B, as shown in FIG. 17C. In some embodiments, portions of the sidewall dielectric layers 152A are suspended in the lower portions 354A2 of the contact trenches 354A, as shown in FIG. 17C. In some embodiments, portions of the sidewall dielectric layers 152B are suspended in the lower portions 354B2 of the contact trenches 354B, as shown in FIG. 17C. In some embodiments, the remaining portions of the source/drain features 132A have the width W1 in the Y-direction and between the side spacers 126A. In some embodiments, the remaining portions of the source/drain features 132B have the width W3 in the Y-direction and between the side spacers 126B.

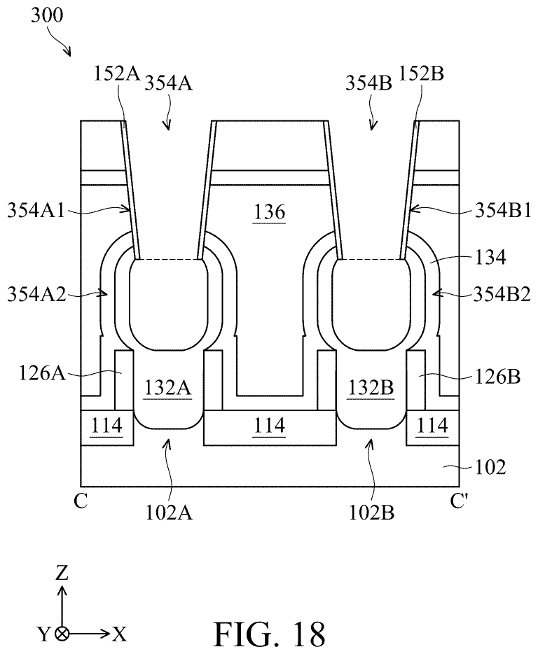

In some embodiments, after the formation of the contact trenches 354A and 354B, remaining portions of the source/drain features 132A and 132B are still separated the contact trenches 354A and 354B from the CESLs 134. In some embodiments, the remaining portions of the source/drain features 132A and 132B are still formed on the sidewalls of the CESLs 134 and cover the side spacers 126A and 126B, as shown in FIG. 18. In these embodiments, the lower portions 354A2 of the contact trenches 354A are surrounded by and are separated from the CESLs 134 and side spacers 126A by the source/drain features 132A in the Y-Z plane shown in FIG. 18. In these embodiments, the lower portions 354B2 of the contact trenches 354B are surrounded by and are separated from the CESLs 134 and side spacers 126B by the source/drain features 132B in the Y-Z plane shown in FIG. 18.

In some embodiments, after the formation of the contact trenches 354A and 354B, a cleaning process is performed to clean surfaces of the workpiece 300. The cleaning process may include a dry clean, a wet clean, or a combination thereof. In some embodiments, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

In some embodiments, an optional doping process is performed to dope p-type dopant (e.g., B or In) into p-type source/drain features, so as to increase the p-type doping concentration in the p-type source/drain features. In some embodiments, the p-type dopant may be doped by using ion implantation or thermal diffusion.

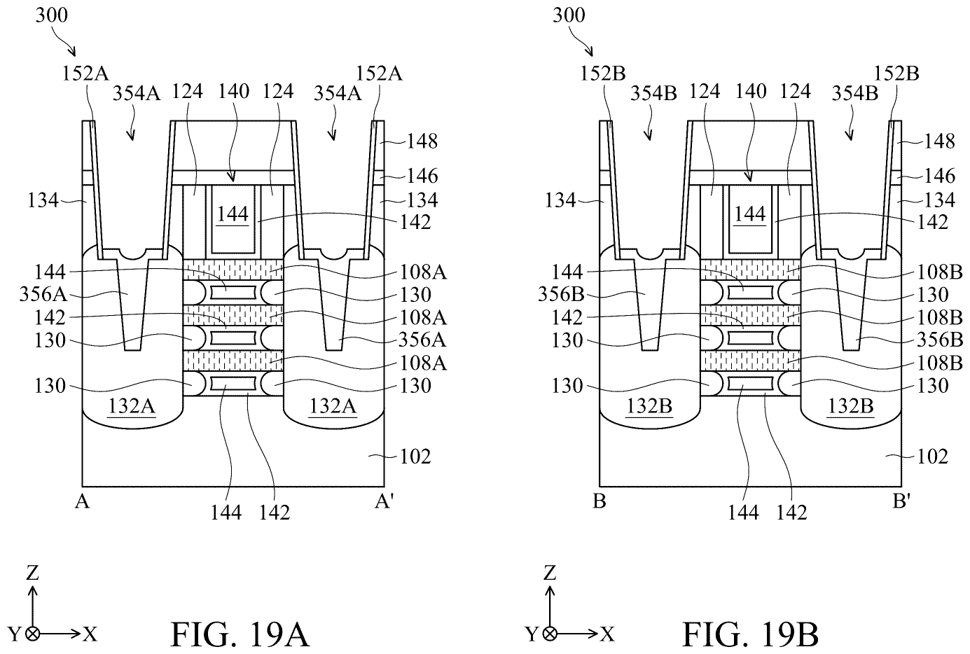

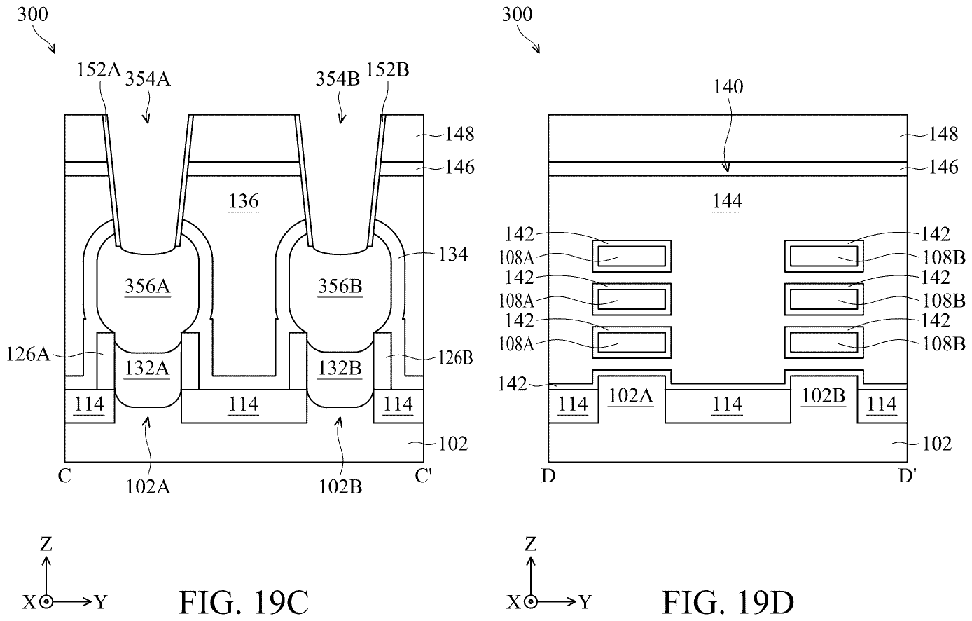

Referring to FIGS. 19A to 19D, silicide layers 356A and silicide layers 356B are formed in the contact trenches 354A and the contact trenches 354B, respectively, in accordance with some embodiments. In some embodiments, silicide layers 356A are formed on the exposed surfaces of the source/drain features 132A in the contact trenches 354A, and silicide layers 356B are formed on the exposed surfaces of the source/drain features 132B in the contact trenches 354B.

In some embodiments, the silicide layers 356A are formed by depositing metal layers on the source/drain features 132A, and heating the workpiece 300 to cause constituents of the source/drain features 132A to react with metal constituents of the metal layers. Similarly, the silicide layers 356B may be formed by depositing metal layers on the source/drain features 132B, and heating the workpiece 300 to cause constituents of the source/drain features 132B to react with metal constituents of the metal layers. In some embodiments, the silicide layers 356A and 356B may include TiSi, NiSi, WSi, NiPtSi, NiPtGeSi, NiGeSi, YbSi, PtSi, IrSi, ErSi, CoSi, or other suitable compounds.

In some embodiments, since the lower portions 354A2 of the contact trenches 354A and the lower portions 354B2 of the contact trenches 354B have small dimensions (e.g., measured in the X-direction), the silicide layers 356A are merged in the lower portions 354A2 and the silicide layers 356B are merged in the lower portions 354B2, as shown in FIGS. 19A to 19D. Since the silicide layers 356A and the silicide layers 356B are merged, the silicide layer 356A may also be referred to as bulk silicide or silicide portion 356A, and the silicide layer 356B may also be referred to as bulk silicide or silicide portion 356B. In some embodiments, in the merged portions, the silicide layers 356A and 356B may have thickness greater than 6 nm. In some embodiments, in the top portions, the silicide layers 356A and 356B may have rounded recesses exposed by the contact trenches 354A and 354B.

Regarding FIG. 18, the remaining portions of the source/drain features 132A and 132B formed on the sidewalls of the CESLs 134 react with the metal layers to form silicide during the formation of the silicide layers 356A and 356B. Therefore, after undergoing the fabrication stage shown in FIGS. 19A to 19D, the structure shown in FIG. 18 may be the same as or similar to the structure shown in FIG. 19C.

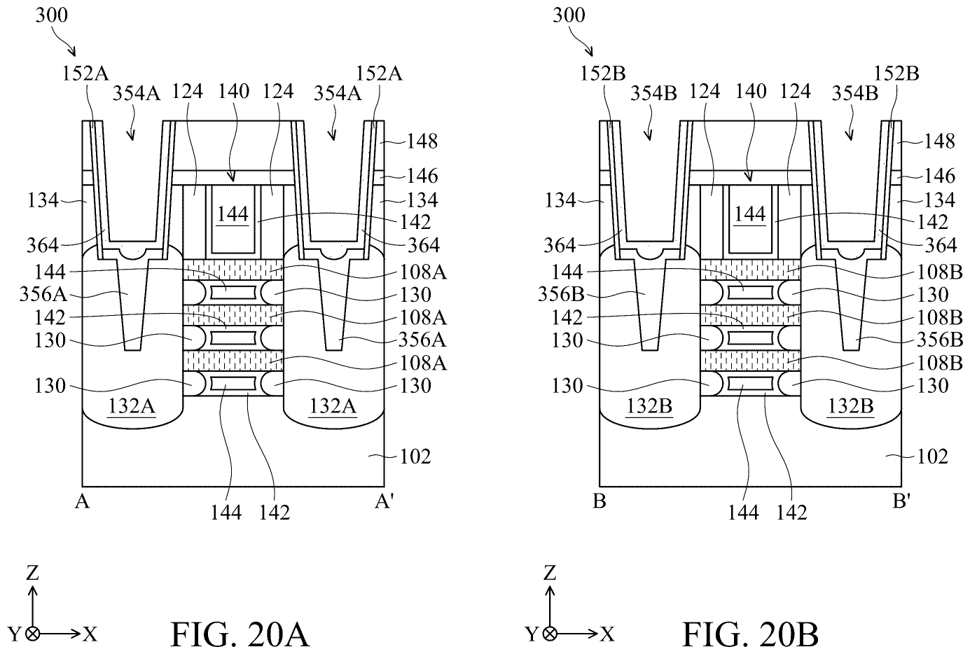

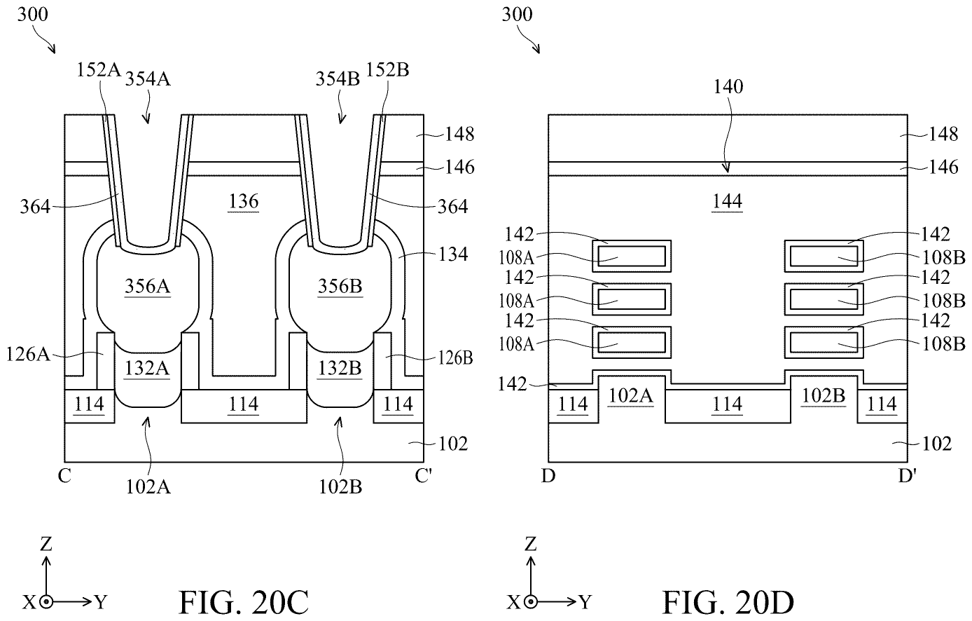

Referring to FIGS. 20A to 20D, conductive layers 364 are formed in the contact trenches 354A and 354B, in accordance with some embodiments. In some embodiments, the conductive layers 364 are conformally formed in the contact trenches 354A and 354B. That is, the sidewalls of the sidewall dielectric layers 152A and 152B and the surfaces of the silicide layers 356A and 356B exposed by the remaining portions of the contact trenches 354A and 354B are covered by the conductive layers 364.

In some embodiments, the material of the conductive layers 364 may include Al, Cu, W, Co, Ti, Ta, Ru, Rh, Ir, Pt, TiN, TiAl, TiAlN, TaN, TaC, combinations thereof, or the like, although any suitable material may be used. The conductive layers 364 may be deposited using a deposition process such as sputtering, CVD, PVD, ALD, HDPCVD, MOCVD, RPCVD, PECVD, LPCVD, ALCVD, APCVD, FCVD, and/or other suitable method.

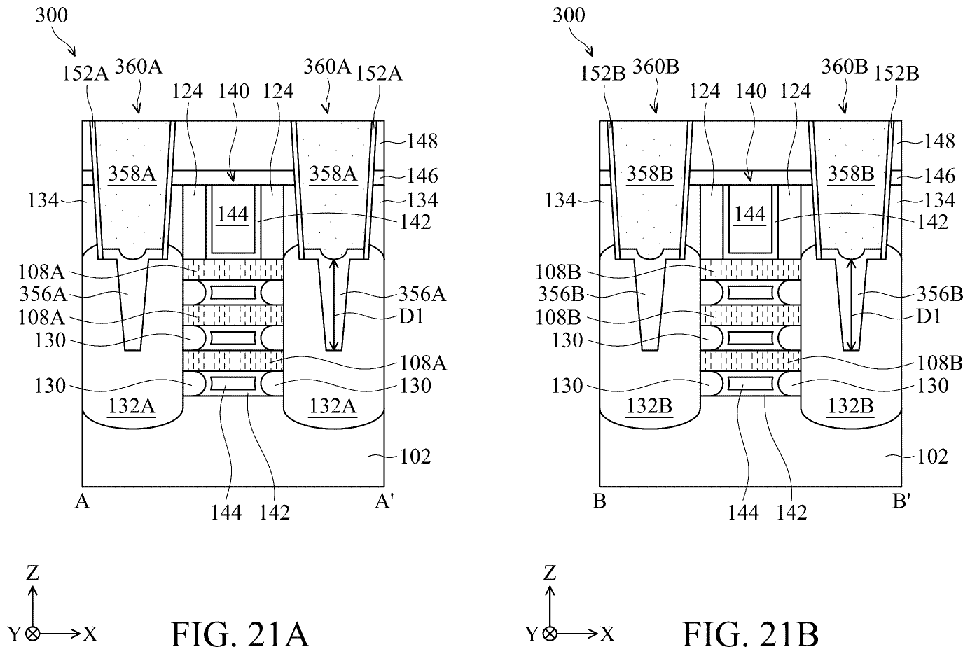

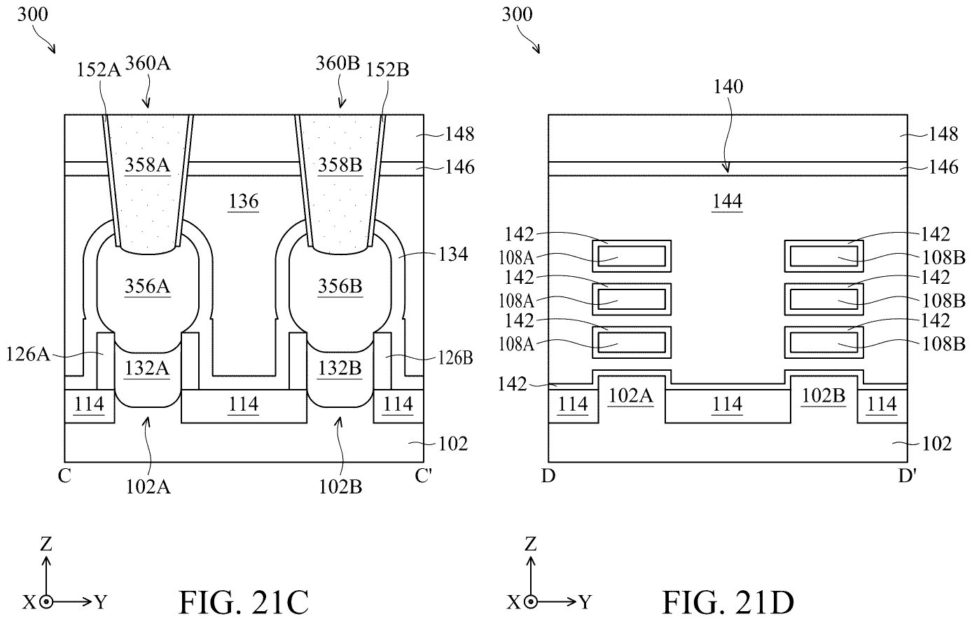

Referring to FIGS. 21A to 21D, vertical portions of the conductive layers 364 formed on sidewalls of the sidewall dielectric layers 152A and 152B are removed, and horizontal portions of the conductive layers 364 formed on silicide layers 356A and 356B are remained, in accordance with some embodiments. In some embodiments, mask layers are formed to cover the horizontal portions of the conductive layers 364 in the contact trenches 354A and 354B by a photolithography process. Then, in some embodiments, an etching process is performed to remove the vertical portions of the conductive layers 364 exposed by the mask layers. The etching process may be a selective etching process that selectively etches the conductive layers 364, with minimal etching (or substantially no etching) of the mask layers, the ILD layers 148, and the sidewall dielectric layers 152A and 152B. The selective etching process may be a dry etching process, a wet etching process, other suitable etching process, or combinations thereof.

Then, in some embodiments, the mask layers are removed from the contact trenches 354A and 354B, so as to expose the horizontal portions of the conductive layers 364. For example, the mask layers may be photoresist layers and the removal of the mask layers may include an ashing or stripping process. After removing the vertical portions of the conductive layers 364, the horizontal portions of the conductive layers 364 remain and may function as seed layers to facilitate the deposition of the conductive material described below.

Still referring to FIGS. 21A to 21D, metal portions 358A are formed on the silicide layers 356A and in the contact trenches 354A, and metal portions 358B are formed on the silicide layers 356B and in the contact trenches 354B, in accordance with some embodiments. The source/drain contacts 360A may each include the silicide layer 356A and the metal portion 358A, and the source/drain contacts 360B may each include the silicide layer 356B and the metal portion 358B. In some embodiments, in the middle portions of the source/drain contacts 360A, the silicide layers 356A have a depth D1 in the Z-direction. In some embodiments, the depth D1 is in a range from about 12 nm to about 21 nm, for example, in a range from about 15 nm to about 18 nm. In some embodiments, in the middle portions of the source/drain contacts 360B, the silicide layers 356B have a depth D2 in the Z-direction. In some embodiments, the depth D2 is in a range from about 12 nm to about 21 nm, for example, in a range from about 15 nm to about 18 nm.

In some embodiments, bottom surfaces of the source/drain contacts 360A are lower than the second bottommost semiconductor layer 108A. For example, the bottom surfaces of the source/drain contacts 360A are lower than the top surface of the second bottommost semiconductor layer 108A and higher than the bottom surface of the bottommost semiconductor layer 108A. In some embodiments, bottom surfaces of the source/drain contacts 360B are lower than the second bottommost semiconductor layer 108B. For example, the bottom surfaces of the source/drain contacts 360B are lower than the top surface of the second bottommost semiconductor layer 108B and higher than the bottom surface of the bottommost semiconductor layer 108B.

In some embodiments, a conductive material is deposited in the contact trenches 354A and 354B and on the remaining horizontal portions of the conductive layers 364 by a deposition process. In the contact trenches 354A, the deposited conductive material and the horizontal portions of the conductive layers 364 form the metal portions 358A of the source/drain contacts 360A. In the contact trenches 354B, the deposited conductive material and the horizontal portions of the conductive layers 364 form the metal portions 358B of the source/drain contacts 360B. The conductive material may include Al, Cu, W, Co, Ti, Ta, Ru, Rh, Ir, Pt, TiN, TiAl, TiAlN, TaN, TaC, combinations thereof, or the like, although any suitable material may be used. In some embodiments, the conductive material includes the same material as the conductive layers 364. The conductive material may be deposited using a deposition process such as sputtering, CVD, PVD, ALD, HDPCVD, MOCVD, RPCVD, PECVD, LPCVD, ALCVD, APCVD, FCVD, and/or other suitable method.

In some embodiments, the metal portions 358A are surrounded by the sidewall dielectric layers 152A. In some embodiments, the metal portions 358B are surrounded by the sidewall dielectric layers 152B. In some embodiments, the metal portions 358A have protrusions extending into the silicide layers 356A, and the metal portions 358B have protrusions extending into the silicide layers 356B. In some embodiments, the protrusions of the metal portions 358A and 358B have rounded shapes. In further embodiments, the protrusions of the metal portions 358A and 358B have shield-boss shapes in the X-Z planes shown in FIGS. 21A and 21B.

In some embodiments, the silicide layers 356A have awl-shapes or cone-shapes in the X-Z plane, shown in FIG. 21A. In some embodiments, the silicide layers 356A are in partial contact with the sidewall dielectric layers 152A. In some embodiments, the silicide layers 356A are adjacent to and surrounded by the CESLs 134 in the Y-Z plane, as shown in FIG. 21C. In some embodiments, the silicide layers 356A are attached to or in partial contact with the side spacers 126A, as shown in FIG. 21C. In some embodiments, the metal portions 358A are separated from the side spacers 126A by the silicide layers 356A.

In some embodiments, the silicide layers 356B have awl-shapes or cone-shapes in the X-Z plane, shown in FIG. 21B. In some embodiments, the silicide layers 356B are in partial contact with the sidewall dielectric layers 152B. In some embodiments, the silicide layers 356B are adjacent to and surrounded by the CESLs 134 in the Y-Z plane, as shown in FIG. 21C. In some embodiments, the silicide layers 356B are attached to or in partial contact with the side spacers 126B, as shown in FIG. 21C. In some embodiments, the metal portions 358B are separated from the side spacers 126B by the silicide layers 356B.

Similar to the source/drain contacts 160A and 160B, the source/drain contacts 360A and 360B have larger volume to reduce their own bulk resistivity, and provide larger contact area between the source/drain contacts 360A and 360B and the source/drain features 132A and 132B, so as to reduce the contact resistance between the source/drain contacts 360A and 360B and the source/drain features 132A and 132B. Similar to the source/drain contacts 160A and 160B, for the source/drain contacts 360A and 360B, the critical dimensions can be maintained, the depths can be controlled, and the shapes can be controlled. Moreover, the source/drain contacts 360A and 360B can be closer to the bottommost semiconductor layer 108A/108B, so as to mitigate the current crowding effect.

Furthermore, by forming the merged silicide layers 356A and 356B in lower parts of the contact trenches 354A and 354B, the gap fill issue due to small dimensions or high aspect ratio can be avoided. Moreover, the merged silicide layers 356A and 356B in a bulk form can fill lower parts of the contact trenches 354A and 354B with awl-shapes, so as to reduce heterojunction area between the silicide layer 356A and 356B and the metal portions 358A and 358B. In this way, the resistance inside the source/drain contacts 360A and 360B can be reduced, so that the contact resistance between the source/drain contacts and the source/drain features can be reduced further. In addition, by applying the GAA transistors provided herein into a ring oscillator (RO) architecture, the performance of RO gain can be improved by 2% to 3%.

The embodiments disclosed herein relate to semiconductor structures and their forming methods, and more particularly to methods and semiconductor structures that include extending the S/D trench for forming the deep S/D contact. The deep S/D contact has larger volume to reduce its own bulk resistivity, and provides larger contact area between the S/D contact and the S/D feature to reduce the contact resistance between the S/D contact and the S/D feature. Moreover, since the deep S/D contact is closer to the lower nanostructure, so it can promote the access to the lower channel, so as to mitigate the current crowding effect. Furthermore, the extended S/D trench may be formed as including a lower portion with awl-shape, such that the portion of silicide layer formed in the lower portion is merged into a bulk silicide. The silicide in a form of bulk can reduce the resistance between the metal portion and the silicide portion inside the S/D contact, so as to reduce contact resistance between the S/D contact and the S/D feature further.

In one exemplary aspect, the present disclosure is directed to a method of forming a semiconductor structure. The method includes forming a fin structure, forming a dummy gate structure over the fin structure, forming gate spacers on opposite sides of the dummy gate structure in a first direction, and forming side spacers on opposite sides of the fin structure in a second direction. The fin structure includes a protrusion and first semiconductor layers and second semiconductor layers alternately stacked over the protrusion. The second direction is perpendicular to the first direction. The method further includes forming source/drain features on the opposite sides of the dummy gate structure in the first direction, forming contact etch stop layers (CESLs) on the source/drain features and forming first interlayer dielectric (ILD) layers on the CESLs, and replacing the dummy gate structure and the first semiconductor layers with a metal gate structure. The source/drain features extend into the protrusion. The metal gate structure surrounds the second semiconductor layers. The method further includes forming trenches extending through the CESLs and the first ILD layers and exposing the source/drain features, etching the source/drain features to extend the trenches in the source/drain features in a vertical direction to form contact trenches, and forming source/drain contacts in the contact trenches. The vertical direction is perpendicular to the first direction and the second direction. The bottom surfaces of the trenches are higher than a bottom surface of a topmost one of the second semiconductor layers, and the bottom surfaces of the contact trenches are lower than a top surface of a second bottommost one of the second semiconductor layers. At least one of the source/drain contacts includes a silicide layer formed on surfaces of the source/drain features exposed by the contact trenches and a metal portion formed on the silicide layer.

In another exemplary aspect, the present disclosure is directed to a method of forming a semiconductor structure. The method includes forming a fin structure including first semiconductor layers and second semiconductor layers alternately stacked in a vertical direction on a substrate, forming a dummy gate structure on the fin structure, forming gate spacers on opposite sides of the dummy gate structure in a first direction, and forming side spacers on opposite sides of the fin structure in a second direction. The first direction, the second direction, and the vertical direction are perpendicular to each other. The method further includes forming source/drain trenches on the opposite sides of the dummy gate structure in the first direction, forming source/drain features in the source/drain trenches, and forming first portions of contact trenches over and exposing the source/drain features. The gate spacers are between the source/drain trenches and the dummy gate structure. The source/drain features extend into the substrate. The method further includes forming sidewall dielectric layers on sidewalls of the first portions of the contact trenches, performing a first etching process to etch the source/drain features through the first portions to form second portions of the contact trenches, and forming source/drain contacts in the first portions and the second portions of the contact trenches. The source/drain contacts include silicide layers formed on surfaces of the source/drain features exposed by the contact trenches and metal portions formed on the silicide layers.

In yet another exemplary aspect, the present disclosure is directed to a semiconductor structure. The semiconductor structure includes a protrusion and nanostructures spaced apart from each other over the protrusion and stacked in a vertical direction, a gate structure wrapped around the nanostructures, source/drain features disposed on opposite sides of the gate structure and adjacent to opposite sides of the nanostructures in a first direction, and side spacers disposed on opposite sides of the source/drain features in a second direction and on lower portions of the source/drain features in the vertical direction. The second direction, the first direction, and the vertical direction are perpendicular to each other. The semiconductor structure further includes contact etch stop layers (CESLs) disposed on the source/drain features, interlayer dielectric (ILD) layers disposed on the CESLs, and a first source/drain contact extending through the ILD layer and the CESL and electrically connected to one of the source/drain features. The bottom surface of the first source/drain contact is lower than the top surface of a second bottommost one of the first nanostructures.

In yet another exemplary aspect, the present disclosure is directed to a method of forming a semiconductor structure. The method includes forming a first fin structure and a second fin structure, forming first side spacers on opposite sides of the first fin structure and second side spacers on opposite sides of the second fin structure in a first direction, forming first source/drain features in the first fin structure and between the first side spacers, and forming second source/drain features in the second fin structure and between the second side spacers. The first fin structure and the second fin structure each includes first semiconductor layers and second semiconductor layers alternately stacked in a vertical direction. The first direction is perpendicular to the vertical direction. The method further includes forming contact etch stop layers (CESLs) on the first source/drain features and the second source/drain features, and forming first trenches and second trenches extending through the CESLs. The first trenches and the second trenches expose the first source/drain features and the second source/drain features, respectively. The method further includes performing a first etching process to extend the first trenches and the second trenches, so as to form first contact trenches and second contact trenches, respectively, and forming first source/drain contacts and second source/drain contacts in the first contact trenches and the second contact trenches, respectively. A first depth of the first contact trenches is greater than a second depth of the second contact trenches. The first source/drain contacts include first portions that are attached to the CESLs, and the second source/drain contacts include third portions that are attached to the CESLs.

In some embodiments, the method further includes forming first sidewall dielectric layers on sidewalls of the first trenches, and forming second sidewall dielectric layers on sidewalls of the second trenches. The first source/drain contacts include second portions that are surrounded by the first sidewall dielectric layers, and the second source/drain contacts include fourth portions that are surrounded by the second sidewall dielectric layers.

In some embodiments, the method further includes forming first silicide layers on surfaces of the first source/drain features exposed by the first contact trenches, and forming second silicide layers on surfaces of the second source/drain features exposed by the second contact trenches.

In some embodiments, the first silicide layers and the first portions of the first source/drain contacts are attached to the first side spacers. The second silicide layers and the third portions of the second source/drain contacts are spaced apart from the second side spacers by the second source/drain features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure comprising a protrusion and first semiconductor layers and second semiconductor layers alternately stacked over the protrusion;
forming a dummy gate structure over the fin structure;
forming gate spacers on opposite sides of the dummy gate structure in a first direction and forming side spacers on opposite sides of the fin structure in a second direction, wherein the second direction is perpendicular to the first direction;
forming source/drain features on the opposite sides of the dummy gate structure in the first direction, wherein the source/drain features extend into the protrusion;
forming contact etch stop layers (CESLs) on the source/drain features and forming first interlayer dielectric (ILD) layers on the CESLs;
replacing the dummy gate structure and the first semiconductor layers with a metal gate structure so that the metal gate structure surrounds the second semiconductor layers;
forming trenches extending through the CESLs and the first ILD layers and exposing the source/drain features, wherein bottom surfaces of the trenches are higher than a bottom surface of a topmost one of the second semiconductor layers;
etching the source/drain features to extend the trenches in the source/drain features in a vertical direction to form contact trenches, wherein the vertical direction is perpendicular to the first direction and the second direction, and wherein bottom surfaces of the contact trenches are lower than a top surface of a second bottommost one of the second semiconductor layers; and
forming source/drain contacts in the contact trenches, wherein at least one of the source/drain contacts comprises a silicide layer formed on surfaces of the source/drain features exposed by the contact trenches and a metal portion formed on the silicide layer.

2. The method of claim 1, further comprising:
before forming the contact trenches, depositing a dielectric material layer in the trenches; and
removing horizontal portions of the dielectric material layer to form sidewall dielectric layers on sidewalls of the trenches.

3. The method of claim 2,
wherein the metal portion of the at least one of the source/drain contacts comprises a first portion and a second portion, and
wherein the first portion is adjacent to the CESLs, and the second portion is adjacent to the sidewall dielectric layer.

4. The method of claim 1, further comprising:
etching the fin structure to form source/drain trenches on the opposite sides of the dummy gate structure in the first direction, wherein the source/drain trenches extend into the protrusion,
wherein the source/drain features are formed in the source/drain trenches.

5. The method of claim 1,
wherein the contact trenches partially expose the side spacers, and
wherein the silicide layer of the at least one of the source/drain contacts are adjacent to the side spacers.

6. The method of claim 1,
wherein before forming the contact trenches, in a cross-sectional view, at least one of the source/drain features comprises a third portion lower than top surfaces of the side spacers and a fourth portion above the top surfaces of the side spacers,
wherein in the second direction, the third portion has a first width that is less than a second width of the fourth portion, and
wherein after forming the contact trenches, in the cross-sectional view, a remaining portion of the at least one of the source/drain features has the first width.

7. The method of claim 6,
wherein the metal portion of the at least one of the source/drain contacts comprises a first portion adjacent to the CESLs, and
wherein in the cross-sectional view, the first portion of the metal portion has the second width.

8. A method of forming a semiconductor structure, comprising:
forming a fin structure comprising first semiconductor layers and second semiconductor layers alternately stacked in a vertical direction on a substrate;
forming a dummy gate structure on the fin structure;
forming gate spacers on opposite sides of the dummy gate structure in a first direction and forming side spacers on opposite sides of the fin structure in a second direction, wherein the first direction, the second direction, and the vertical direction are perpendicular to each other;
forming source/drain trenches on the opposite sides of the dummy gate structure in the first direction, wherein the gate spacers are between the source/drain trenches and the dummy gate structure;
forming source/drain features in the source/drain trenches, wherein the source/drain features extend into the substrate;
forming first portions of contact trenches over and exposing the source/drain features;
forming sidewall dielectric layers on sidewalls of the first portions of the contact trenches;
performing a first etching process to etch the source/drain features through the first portions, so as to form second portions of the contact trenches; and
forming source/drain contacts in the first portions and the second portions of the contact trenches, wherein the source/drain contacts comprise silicide layers formed on surfaces of the source/drain features exposed by the contact trenches and metal portions formed on the silicide layers.

9. The method of claim 8, further comprising:
depositing protection layers on the sidewall dielectric layers and bottom surfaces of the first portions of the contact trenches,
wherein the protection layers are also etched during the first etching process.

10. The method of claim 9, wherein in a first cross-sectional view constituted by the vertical direction and the first direction, the first portions of the contact trenches have a trapezoid shape and the second portions of the contact trenches have an awl shape.

11. The method of claim 9, wherein the silicide layers of the source/drain contacts are merged in lower portions of the second portions of the contact trenches.

12. The method of claim 9, wherein in a first cross-sectional view constituted by the vertical direction and the first direction, the metal portions of the source/drain contacts comprise rounded protrusions extending into the silicide layers.

13. The method of claim 8, further comprising:
forming contact etch stop layers (CESLs) on the source/drain features and forming first interlayer dielectric (ILD) layers on the CESLs,
wherein the first portions of the contact trenches extend through the CESLs and the first ILD layers,
wherein in a second cross-sectional view constituted by the vertical direction and the second direction, the silicide layers are adjacent to the side spacers and formed between the CESLs in the second direction.

14. The method of claim 13, wherein in the second cross-sectional view, the second portions of the contact trenches partially expose the CESLs and the side spacers.

15. A semiconductor structure, comprising:
a first protrusion and first nanostructures spaced apart from each other over the first protrusion, and stacked in a vertical direction;
a first gate structure, wrapped around the first nanostructures;
first source/drain features, disposed on opposite sides of the first gate structure and adjacent to opposite sides of the first nanostructures in a first direction;
first side spacers, disposed on opposite sides of the first source/drain features in a second direction and on lower portions of the first source/drain features in the vertical direction, wherein the second direction, the first direction, and the vertical direction are perpendicular to each other;
first contact etch stop layers (CESLs), disposed on the first source/drain features;
first interlayer dielectric (ILD) layers, disposed on the first CESLs; and
a first source/drain contact, extending through the first ILD layer and the first CESL and electrically connected to one of the first source/drain features,
wherein a bottom surface of the first source/drain contact is lower than a top surface of a second bottommost one of the first nanostructures.

16. The semiconductor structure of claim 15, wherein the first source/drain contact comprises a first silicide layer that is adjacent to the first side spacers and a first metal portion disposed on the first silicide layer.

17. The semiconductor structure of claim 16, further comprising:
a sidewall dielectric layer, wherein the first metal portion of the first source/drain contact comprises a first portion adjacent to the first CESLs and a second portion adjacent to the sidewall dielectric layer,
wherein the sidewall dielectric layer is disposed between the second portion and the first CESL and the first ILD layer.

18. The semiconductor structure of claim 16,
wherein the first silicide layer of the first source/drain contact is surrounded by and adjacent to the first CESL, and
wherein the first metal portion of the first source/drain contact comprises a rounded protrusion extending into the silicide layer.

19. The semiconductor structure of claim 15, further comprising:
a second protrusion and second nanostructures spaced apart from each other over the second protrusion, and stacked in the vertical direction;
a second gate structure, wrapped around the second nanostructures;
second source/drain features, disposed on opposite sides of the second gate structure and adjacent to opposite sides of the second nanostructures in the first direction;
second CESLs, disposed on the second source/drain features;
second ILD layers, disposed on the second CESLs; and
a second source/drain contact, extending through the second ILD layer and the second CESL and electrically connected to one of the second source/drain features,
wherein a bottom surface of the second source/drain contact is higher than the bottom surface of the first source/drain contact.

20. The semiconductor structure of claim 19, further comprising:
second side spacers, disposed on opposite sides of the second source/drain features in the second direction and on lower portions of the second source/drain features in the vertical direction,
wherein the second source/drain contact comprises a second silicide layer disposed on the second source/drain features and a second metal portion disposed on the second silicide layer,
wherein the second silicide layer is separated from the second side spacers by the second source/drain features.
